(19) United States
(12) Patent Application Publication
(10) Pub. No.: US 2025/0151388 A1
(43) Pub. Date: May 8, 2025

(54) SEMICONDUCTOR DEVICE

(71) Applicant: SAMSUNG ELECTRONICS CO., LTD., Suwon-si (KR)

(72) Inventors: Dahye Kim, Suwon-si (KR); Jae Hyun Park, Suwon-si (KR); Jinchan Yun, Suwon-si (KR); Daihong Huh, Suwon-si (KR)

(21) Appl. No.: 18/738,621

(22) Filed: Jun. 10, 2024

(30) Foreign Application Priority Data
Nov. 6, 2023 (KR) 10-2023-0151704

(51) Int. Cl. H01L 27/092; H01L 21/822; H01L 21/8238; H01L 29/06; H01L 29/08; H01L 29/417; H01L 29/423; H01L 29/66; H01L 29/775; H01L 29/786

(52) U.S. Cl. CPC H10D 84/856; H10D 30/014; H10D 30/031; H10D 30/43; H10D 30/6729; H10D 30/6735; H10D 30/6757; H10D 62/121; H10D 62/151; H10D 64/017; H10D 84/0167; H10D 84/017; H10D 84/0186; H10D 84/038; H10D 88/01

(57) ABSTRACT

A semiconductor device incudes: a plurality of lower channel patterns apart from each other; a plurality of upper channel patterns spaced apart from each other on the plurality of lower channel patterns; a gate structure surrounding the plurality of lower channel patterns and the plurality of upper channel patterns; a lower source/drain trench positioned on at least one side of the plurality of lower channel patterns; an upper source/drain trench positioned on at least one side of the plurality of upper channel patterns; a lower source/drain pattern positioned within the lower source/drain trench; and an upper source/drain pattern including first upper source/drain layers positioned on opposite sidewalls of the upper source/drain trench, and a second upper source/drain layer positioned between the first upper source/drain layers, in which the first upper source/drain layer does not cover at least a portion of the bottom surface of the upper source/drain trench.

### CROSS-REFERENCE TO RELATED APPLICATION

This application claims priority to and the benefit of Korean Patent Application No. 10-2023-0151704 filed in the Korean Intellectual Property Office on Nov. 6, 2023, the entire contents of which are incorporated herein by reference.

### BACKGROUND

A semiconductor is a material belonging to a middle region between a conductor and a nonconductor and refers to a material that conducts electricity under certain conditions. Various semiconductor devices may be manufactured by using these semiconductor materials, and for example, memory devices and the like may be manufactured. Such semiconductor devices may be used in various electronic devices.

As the electronic industry progressively develops, demands on the characteristics of semiconductor devices are gradually increasing. For example, demands for high reliability, high speed, and/or multifunctionality of semiconductor devices are gradually increasing. In order to satisfy these required characteristics, structures within semiconductor devices are becoming increasingly complex and integrated.

### SUMMARY

The present disclosure attempts to provide a semiconductor device with improved reliability.

An implementation of the present disclosure provides a semiconductor device including: a plurality of lower channel patterns stacked while being spaced apart from each other; a plurality of upper channel patterns stacked while being spaced apart from each other on the plurality of lower channel patterns; a gate structure surrounding the plurality of lower channel patterns and the plurality of upper channel patterns; a lower source/drain trench positioned on at least one side of the plurality of lower channel patterns; an upper source/drain trench positioned on at least one side of the plurality of upper channel patterns; a lower source/drain pattern positioned within the lower source/drain trench; and an upper source/drain pattern including first upper source/drain layers positioned on opposite sidewalls of the upper source/drain trench, and a second upper source/drain layer positioned between the first upper source/drain layers, in which the first upper source/drain layers expose at least a portion of the bottom surface of the upper source/drain trench.

Another implementation of the present disclosure provides a semiconductor device including: a plurality of upper channel patterns stacked while being spaced apart from each other; a gate structure surrounding the plurality of upper channel patterns; an upper source/drain trench positioned on at least one side of the plurality of upper channel patterns; and an upper source/drain pattern including first upper source/drain layers protruding from opposite sidewalls of the upper source/drain trench, and a second upper source/drain layer positioned between the first upper source/drain layers, in which a width of the first upper source/drain layers along one direction gradually increases from an upper portion and a lower portion of the upper source/drain trench toward a center portion.

Still another implementation of the present disclosure provides a semiconductor device including: a substrate; an active pattern positioned on the substrate; a plurality of lower channel patterns stacked while being spaced apart on the active pattern; a plurality of upper channel patterns stacked while being spaced apart on the plurality of lower channel patterns; a gate structure surrounding the plurality of lower channel patterns and the plurality of upper channel patterns; a lower source/drain pattern positioned on at least one side of the plurality of lower channel patterns; an upper source/drain pattern including first upper source/drain layers and a second upper source/drain layer positioned on at least one side of the plurality of upper channel patterns; and a barrier structure positioned between the lower source/drain pattern and the upper source/drain pattern, in which the first upper source/drain layer is positioned on opposite sides of the second upper source/drain layer, and a width of the first upper source/drain layer along one direction gradually increases from an upper portion and a lower portion of the upper source/drain trench toward a center portion of the upper source/drain trench.

According to the implementations, it is possible to secure reliability of a semiconductor device.

### BRIEF DESCRIPTION OF THE DRAWINGS

FIG. 1 is a top plan view of an example semiconductor device.

FIG. 2 is a cross-sectional view taken along I-I′ of FIG. 1.

FIG. 3 is a cross-sectional view taken along II-II′ of FIG. 1.

FIG. 4 is a cross-sectional view taken along III-III′ of FIG. 1.

FIG. 5 is a cross-sectional view of enlarged region A1 of FIG. 2.

FIGS. 6 to 12 are cross-sectional views corresponding to region A1 of FIG. 2 of semiconductor devices.

FIG. 13 is a cross-sectional view corresponding to a region taken along III-III′ of FIG. 1 of the semiconductor devices.

FIGS. 14 and 15 are cross-sectional views corresponding to region A1 of FIG. 2 of the semiconductor devices.

FIGS. 16 and 17 are cross-sectional views corresponding to a region taken along I-I′ of FIG. 1 of the semiconductor devices.

FIG. 18 is a cross-sectional view corresponding to a region taken along I-I′ of FIG. 1 of the semiconductor devices.

FIG. 19 is a cross-sectional view corresponding to a region taken along II-II′ of FIG. 1 of the semiconductor devices.

FIG. 20 is a cross-sectional view corresponding to a region taken along III-III′ of FIG. 1 of the semiconductor device.

FIGS. 21 to 53 are cross-sectional views illustrating an example method of manufacturing a semiconductor device.

### DETAILED DESCRIPTION

In the following detailed description, only certain implementations of the present disclosure have been illustrated and described, simply by way of illustration. The present disclosure may be variously implemented and is not limited to the following implementations.

The drawings and description are to be regarded as illustrative in nature and not restrictive. Like reference numerals designate like elements throughout the specification.

In addition, the size and thickness of each configuration illustrated in the drawings are arbitrarily illustrated for understanding and ease of description, but the present disclosure is not limited thereto. In the drawings, the thickness of layers, films, panels, regions, etc., are exaggerated for clarity. In the drawings, for understanding and ease of description, the thickness of some layers and areas is exaggerated.

It will be understood that when an element such as a layer, film, region, or substrate is referred to as being “on” another element, it may be directly on the other element or intervening elements may also be present. In contrast, when an element is referred to as being “directly on” another element, there are no intervening elements present. Further, it will be understood that when an element such as a layer, film, region, or substrate is referred to as being “on” another element, it may be directly on the other element or intervening elements may also be present.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “in a plan view”, it means when a target part is viewed from above, and when it is referred to as “in a cross-sectional view”, it means when the cross-section obtained by cutting a target part vertically is viewed from the side.

In a drawing of a semiconductor device, a semiconductor device may be formed in a Gate All Around (GAA) structure, a 3D Stack Field Effect Transistor (3DSFET) structure, or the like, where all four sides of a channel are surrounded by gate electrodes. However, the present disclosure is not limited thereto, a transistor may be in a Fin Field Effect Transistor (FinFET) structure, a Multi Bridge Channel Field Effect Transistor (MBCFET™) structure, a Complementary Field Effect Transistor (CFET) structure, and the like.

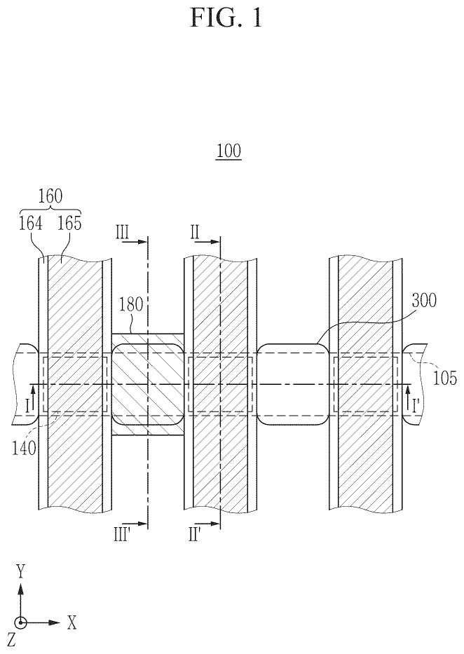

Hereinafter, an example semiconductor device will be described with reference to FIGS. 1 to 5.

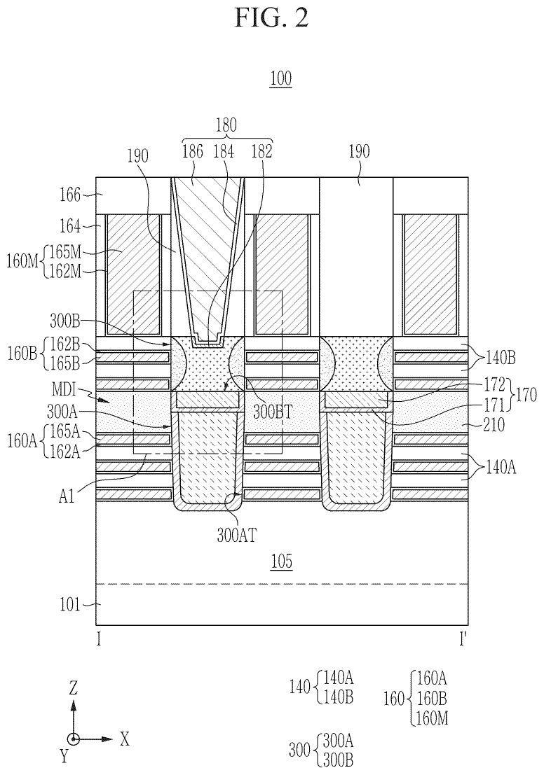

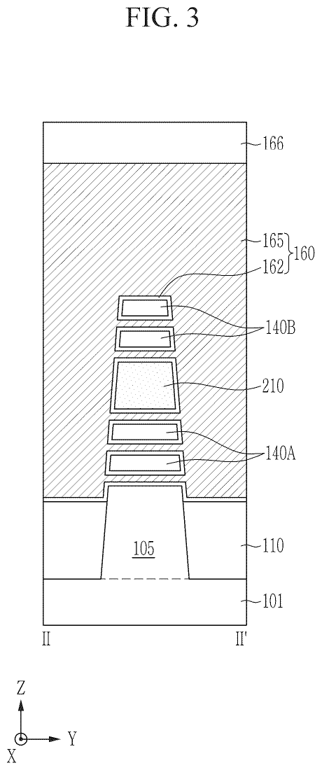

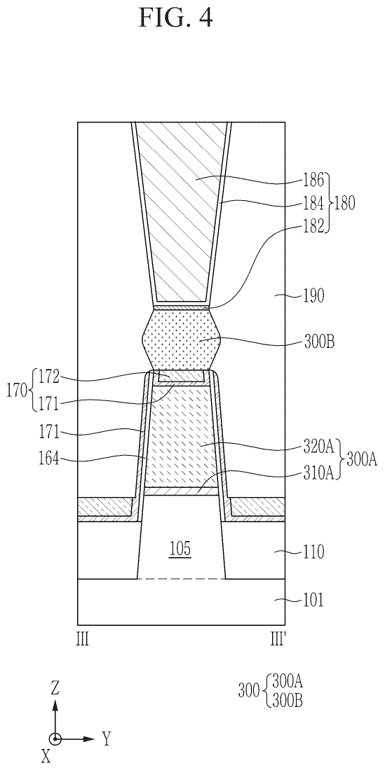

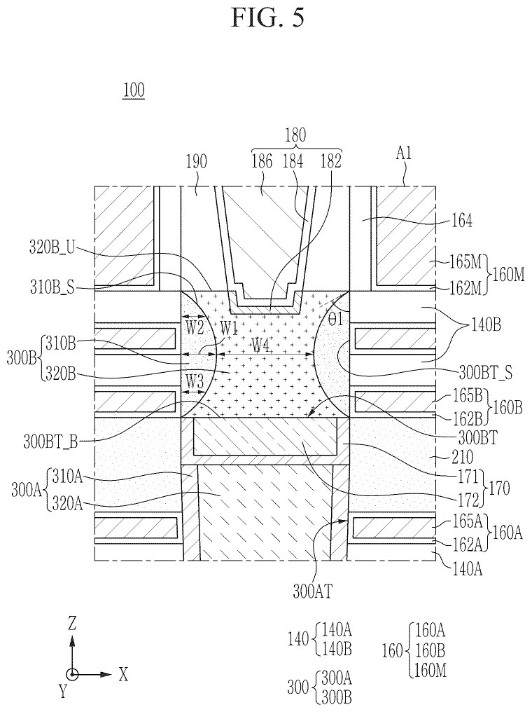

FIG. 1 is a top plan view of an example semiconductor device. FIG. 2 is a cross-sectional view taken along I-I′ of FIG. 1. FIG. 3 is a cross-sectional view taken along II-II′ of FIG. 1. FIG. 4 is a cross-sectional view taken along III-III′ of FIG. 1. FIG. 5 is a cross-sectional view of enlarged region A1 of FIG. 2.

First, referring to FIGS. 1 to 4, an example semiconductor device may include a substrate 101, an active pattern 105 positioned on the substrate 101, a plurality of channel patterns 140 positioned on the active pattern 105, a middle dielectric isolation structure MDI positioned between a plurality of lower channel patterns 140A and a plurality of upper channel patterns 140B, a field insulation layer 110 positioned over the substrate 101, a gate structure 160 positioned on the active pattern 105, source/drain patterns 300 positioned on at least one side of the gate structure 160, and a barrier structure 170 positioned between the lower source/drain pattern 300A and the upper source/drain pattern 300B.

The substrate 101 may be silicon-on-insulator (SOI) or bulk silicon. Alternatively, the substrate 101 may be a silicon substrate or may include other materials, such as silicon germanium (SiGe), silicon germanium on insulator (SGOI), indium antimonide, lead telluride compound, indium arsenide, indium phosphide, gallium arsenide, or gallium antimonide but is not limited thereto. In another example, the substrate 101 may be an insulating substrate including an insulating material.

The substrate 101 may include a top surface and a bottom surface. The top surface and the bottom surface of the substrate 101 may include planes parallel to a first direction (X-direction) and a second direction (Y-direction) intersecting the first direction (X direction). The top surface of the substrate 101 may be a face opposite the bottom surface of the substrate 101 in a third direction (Z direction). The top surface of the substrate 101 may be referred to as a front side. A bottom surface of the substrate 101 may be referred to as a back side. In some implementations, a logic circuit of a cell region may be implemented on the top surface of the substrate 101.

The active pattern 105 may be positioned on the substrate 101. The active pattern 105 may extend in the first direction (X direction). The active pattern 105 may have a structure that protrudes from the substrate 101. A top surface of the active pattern 105 may be positioned to protrude from a top surface of the field insulation layer 110, which will be described later but is not limited thereto. The active pattern 105 may also be formed by etching a portion of the substrate 101 or may include an epitaxial layer grown from the substrate 101. The active pattern 105 may include an elemental semiconductor material, such as silicon (Si) or germanium (Ge). The active pattern 105 may include impurities or may include doped regions containing impurities. As another example, an insulating pattern including an insulating material may be applied instead of the active pattern 105.

The example semiconductor device 100 according to the may include at least one transistor structure. For example, the example semiconductor device 100 may include a first transistor structure including a plurality of lower channel patterns 140A and a second transistor structure including a plurality of upper channel patterns 140B. The first and second transistor structures according to the implementation may be made in a Gate All Around Field Effect Transistor (GAAFET) structure, such as a Multi-Bridge Channel Field Effect Transistor (MBCFET™), in which the plurality of lower channel patterns 140A and the plurality of upper channel patterns 140B are surrounded by the gate structure 160.

Furthermore, the first and second transistor structures may be made in a three dimensional-Stacked FET (3D-SFET) structure stacked in the third direction (Z direction). In this case, the first transistor structure may be any one of an N-type MOSFET and a P-type MOSFET, and the second transistor structure may be the other of a P-type MOSFET and an N-type MOSFET. In the implementation, the first and second transistor structures may be an N-type MOSFET and a P-type MOSFET, respectively, but are not limited thereto. Hereinafter, a case where a plurality of lower channel patterns 140A and a plurality of upper channel patterns 140B are stacked in the third direction (Z direction) to form a 3D-SFET structure will be described. However, the present disclosure is not limited to this case.

The plurality of channel patterns 140 may be positioned on the active pattern 105. In the implementation, the plurality of channel patterns 140 may include a plurality of lower channel patterns 140A positioned on the active pattern 105 and a plurality of upper channel patterns 140B positioned on the plurality of lower channel patterns 140A.

The plurality of lower channel patterns 140A may be positioned on the top surface of the active pattern 105. The plurality of lower channel patterns 140A may be spaced apart from the active pattern 105 in the third direction (Z direction). Each of the plurality of lower channel patterns 140A may be spaced apart in the third direction (Z direction). Here, the third direction (Z direction) may be a direction that intersects the first direction (X direction) and the second direction (Y direction). For example, the third direction (Z direction) may be a thickness direction of the substrate 101.

In the implementation, as illustrated in FIG. 3, a width along the second direction (Y direction) of the plurality of lower channel patterns 140A may decrease as it goes away from the top surface of the substrate 101. Furthermore, as illustrated in FIG. 2, the width along the first direction (X direction) of the plurality of lower channel patterns 140A may decrease as it goes away from the top surface of the substrate 101. However, the present disclosure is not limited thereto, and the widths along the second direction (Y direction) of the plurality of lower channel patterns 140A may be substantially the same. Further, the widths along the first direction (X direction) of the plurality of lower channel patterns 140A may be substantially the same. The plurality of upper channel patterns 140B may be positioned on the plurality of lower channel patterns 140A. Specifically, the plurality of upper channel patterns 140B may be positioned on a top surface of the middle dielectric isolation structure MDI positioned on the plurality of lower channel patterns 140A. The plurality of upper channel patterns 140B may be spaced apart from the plurality of lower channel patterns 140A in the third direction (Z direction). For example, the middle dielectric isolation structure MDI may be positioned between the plurality of upper channel patterns 140B and the plurality of lower channel patterns 140A, and the plurality of upper channel patterns 140B may be spaced apart from the plurality of lower channel patterns 140A by the middle dielectric isolation structure MDI in the third direction (Z direction). Each of the plurality of upper channel patterns 140B may be spaced apart in the third direction (Z direction).

In the implementation, as illustrated in FIG. 3, the width along the second direction (Y-direction) of the plurality of upper channel patterns 140B may decrease as it goes away from the top surface of the substrate 101. However, the widths along the second direction (Y direction) of the plurality of upper channel patterns 140B may be substantially the same but are not limited thereto. Also, as illustrated in FIG. 2, the widths along the first direction (X direction) of the plurality of upper channel patterns 140B may be substantially the same but are not limited thereto.

The plurality of lower channel patterns 140A and the plurality of upper channel patterns 140B may be multichannel active patterns. In the implementation, the plurality of lower channel patterns 140A and the plurality of upper channel patterns 140B may have a nanosheet shape and may be semiconductor patterns including a semiconductor material.

The plurality of lower channel patterns 140A and the plurality of upper channel patterns 140B may be formed by etching a portion of the substrate 101 or may include an epitaxial layer grown from the substrate 101. The plurality of lower channel patterns 140A and the plurality of upper channel patterns 140B may include an elemental semiconductor material, such as silicon (Si) or germanium (Ge). Additionally, the plurality of lower channel patterns 140A and the plurality of upper channel patterns 140B may include compound semiconductors, for example, group IV-IV compound semiconductors or group III-V compound semiconductors.

Each of the plurality of lower channel patterns 140A and the plurality of upper channel patterns 140B may include the same material as the active pattern 105 or may include a different material from the active pattern 105.

The group IV compound semiconductor may be, for example, a binary compound or a ternary compound containing at least two of carbon (C), silicon (Si), germanium (Ge), and tin (Sn).

A group III-V compound semiconductor may be, for example, one of a binary compound, a ternary compound, or a quaternary compound formed by combining at least one of the group III elements of aluminum (Al), gallium (Ga), and indium (In) with one of the group V elements of phosphorus (P), arsenic (As), and antimony (Sb).

In the implementation, the active pattern 105 and the plurality of channel patterns 140 may include silicon (Si). In another example, the active pattern 105 and the plurality of channel patterns 140 may include silicon germanium (SiGe). In another example, the active pattern 105 may include silicon (Si) and the plurality of channel patterns 140 may include silicon germanium (SiGe).

In FIGS. 2 and 3, two lower channel patterns 140A and two upper channel patterns 140B are illustrated as stacked spaced apart along the third direction (Z direction), but this is for illustrative purposes only. The number of channel patterns is not limited thereto. For example, the three or more plurality of lower channel patterns 140A and/or the three or more plurality of upper channel patterns 140B may be stacked while being spaced apart along the third direction (Z direction). Alternatively, one lower channel pattern 140A and/or one upper channel pattern 140B may be stacked while being spaced apart along the third direction (Z direction).

The middle dielectric isolation structure MDI may be positioned on the plurality of lower channel patterns 140A. The middle dielectric isolation structure MDI may be positioned between a topmost lower channel pattern 140A, and the bottommost upper channel pattern 140B. Further, the middle dielectric isolation structure MDI may be positioned between the topmost lower gate structure 160A, and the bottommost upper gate structure 160B.

The middle dielectric isolation structure MDI may include a middle dielectric isolation pattern 210. The middle dielectric isolation pattern 210 may include a variety of insulating materials. The middle dielectric isolation pattern 210 may include a silicon oxide, a silicon nitride, a silicon nitroxide, or a combination thereof. The middle dielectric isolation structure MDI may space the plurality of lower channel patterns 140A and the plurality of upper channel patterns 140B from each other.

In the implementation, the middle dielectric isolation structure MDI is described as including a single middle dielectric isolation pattern 210, but the present disclosure is not limited thereto. The middle dielectric isolation structure MDI may also include a plurality of middle dielectric isolation patterns 210. Alternatively, the middle dielectric isolation structure MDI may include a plurality of middle dielectric isolation patterns 210 and semiconductor patterns positioned between the plurality of middle dielectric isolation patterns 210. Even in this case, the plurality of upper channel patterns 140B and the plurality of lower channel patterns 140A may be spaced apart by the middle dielectric isolation structure MDI.

The field insulation layer 110 may be positioned on the substrate 101. The field insulation layer 110 may cover at least a portion of the side of the active pattern 105. For example, as illustrated in FIG. 3, the field insulation layer 110 may cover a portion of the side of the active pattern 105. That is, a portion of the side of the active pattern 105 may be covered by the field insulation layer 110, and the remaining portion of the sidewall of the active pattern 105 may be covered by the gate structure 160, which will be described later. The field insulation layer 110 may overlap the active pattern 105 in the second direction (Y direction). Further, the field insulation layer 110 may not be positioned on the top surface of the active pattern 105. In the implementation, it is illustrated that the top surface of the field insulation layer 110 extends in a direction parallel to the top surface of the substrate 101, but the present disclosure is not limited thereto. For example, the field insulation layer 110 may have a curved top surface with a higher level as it goes adjacent to the active pattern 105.

In FIG. 3, it is illustrated that the field insulation layer 110 covers at least a portion of the side of the active pattern 105, but the present disclosure is not limited thereto. For example, the field insulation layer 110 may entirely cover the side of the active pattern 105. In this case, the side of the active pattern 105 may be completely covered by the field insulation layer 110.

The field insulation layer 110 may include, for example, a film of an oxide, nitride, a nitride oxide, or a combination thereof. The field insulation layer 110 is illustrated as a single film, but is illustrated for illustrative purposes only, and the present disclosure is not limited thereto.

The gate structure 160 may be positioned on the active pattern 105. The gate structure 160 may extend in the second direction (Y direction). The gate structures 160 may be spaced apart in the first direction (X direction). The gate structure 160 may be positioned on the active pattern 105. The gate structures 160 may intersect the active pattern 105. The gate structures 160 may surround each of the plurality of channel patterns 140.

In the implementation, the first and second transistor structures may be configured to share the single gate structure 160. Specifically, the first transistor structure may include a plurality of lower channel patterns 140A, the gate structure 160 surrounding the plurality of lower channel patterns 140A, and a lower source/drain pattern 300A connected to the plurality of lower channel patterns 140A on one side of the gate structure 160. Further, the second transistor structure may include the plurality of upper channel patterns 140B, the gate structure 160 surrounding the plurality of upper channel patterns 140B, and an upper source/drain pattern 300B connected to the plurality of upper channel patterns 140B on one side of the gate structure 160. In this case, as illustrated in FIG. 3, one gate structure 160 surrounds the plurality of lower channel patterns 140A and the plurality of upper channel patterns 140B together, so that the first and second transistor structures may be configured to share one gate structure 160.

The gate structure 160 may include a lower gate structure 160A, an upper gate structure 160B, and a main gate structure 160M. The lower gate structure 160A may be positioned between the plurality of lower channel patterns 140A adjacent in the third direction (Z direction), between the active pattern 105 and the bottommost lower channel pattern 140A, and between the topmost lower channel pattern 140A, and a middle dielectric isolation structure MDI. The upper gate structure 160B may be positioned between the plurality of upper channel patterns 140B adjacent in the third direction (Z direction) and between the bottommost upper channel pattern 140B, and the middle dielectric isolation structure MDI. The main gate structure 160M may be positioned on the topmost upper channel pattern 140B.

The lower gate structure 160A may be adjacent to the lower source/drain pattern 300A, which will be described later. The upper gate structure 160B may be adjacent to the upper source/drain pattern 300B, which will be described later. The main gate structure 160M may be positioned on the lower gate structure 160A, the upper gate structure 160B, and the plurality of upper channel patterns 140B.

According to the implementation, each of the lower gate structure 160A and the upper gate structure 160B may include a plurality of layers, and the plurality of layers may be alternately stacked with the plurality of channel patterns 140. For example, as illustrated in FIGS. 2 and 3, the lower gate structure 160A may include three layers stacked alternately with the plurality of lower channel patterns 140A, and the upper gate structure 160B may include two layers stacked alternately with the plurality of upper channel patterns 140B. However, the present disclosure is not limited thereto, and the number of layers of the lower gate structure 160A and the upper gate structure 160B may be varied.

Each of the lower gate structure 160A and the upper gate structure 160B may include gate electrodes 165A and 165B and gate insulation films 162A and 162B.

The gate electrodes 165A and 165B may be positioned on the active pattern 105. For example, the lower gate electrode 165A may be positioned on the active pattern 105, and the upper gate electrode 165B may be positioned on the lower gate electrode 165A. The gate electrodes 165A and 165B may intersect the active pattern 105. The gate electrodes 165A and 165B may surround the plurality of channel patterns 140. For example, the lower gate electrode 165A may surround the plurality of lower channel patterns 140A, and the upper gate electrode 165B may surround the plurality of upper channel patterns 140B.

Additionally, at least some of the gate electrodes 165A and 165B may be positioned between the plurality of channel patterns 140. For example, the lower gate electrode 165A may be positioned between the plurality of lower channel patterns 140A, and the upper gate electrode 165B may be positioned between the plurality of upper channel patterns 140B. Other portions of the gate electrodes 165A and 165B may be positioned to cover opposite sides of the stacked structure of the gate electrodes 165A and 165B and the plurality of channel patterns 140.

The gate electrodes 165A and 165B may include a conductive material. The gate electrodes 165A and 165B may include at least one of a metal, a metal alloy, a conductive metal nitride, a metal silicide, a doped semiconductor material, a conductive metal oxide, and a conductive metal nitroxide. The gate electrodes 165A and 165B may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAIC-N), titanium aluminum carbide (TiAIC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium Nitride (NbN), niobium Carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof but is not limited thereto. The conductive metal oxide and the conductive metal nitroxide may include an oxidized form of the above material but are not limited thereto. The gate electrodes 165A and 165B may include the same material but are not limited thereto, and the gate electrodes 165A and 165B may also include different materials.

The gate insulation films 162A and 162B may be positioned along the perimeter of the plurality of channel patterns 140. For example, the lower gate insulation film 162A may be positioned along the perimeter of the plurality of lower channel patterns 140A, and the upper gate insulation film 162B may be positioned along the perimeter of the plurality of upper channel patterns 140B. Additionally, the lower gate insulation film 162A may extend along the top surface of the active pattern 105.

The lower gate insulation film 162A may be in direct contact with the active pattern 105, the plurality of lower channel patterns 140A, and the middle dielectric isolation structure MDI. The upper gate insulation film 162B may be in direct contact with the plurality of upper channel patterns 140B and the middle dielectric isolation structure MDI. The gate insulation films 162A and 162B may be interposed between the plurality of channel patterns 140 and the gate electrodes 165A and 165B. The gate insulation films 162A and 162B may include a variety of insulating materials.

In the implementation, the gate insulation films 162A and 162B are illustrated as a single film but are not limited thereto. For example, the gate insulation films 162A and 162B may be multiple films including silicon oxide (SiO₂) and a high dielectric constant material. In this case, the high dielectric constant material may include a material having a higher dielectric constant than silicon oxide (SiO₂), such as hafnium oxide (HfO), aluminum oxide (AlO), or tantalum oxide (TaO).

The main gate structure 160M may be positioned on the upper gate structure 160B and the plurality of upper channel patterns 140B. The main gate structure 160M may be positioned on a top surface of the plurality of upper channel patterns 140B.

The main gate structure 160M may include a main gate electrode 165M and a main gate insulation film 162M.

The main gate electrode 165M may be positioned on the upper gate structure 160B and the plurality of upper channel patterns 140B. The main gate electrode 165M may be positioned on a top surface of the plurality of upper channel patterns 140B. Accordingly, four sides of the plurality of channel patterns 140 may be surrounded by the gate electrodes 165A and 165B and the main gate electrode 165M. The main gate electrode 165M may include the same conductive material as the gate electrodes 165A and 165B. For example, the main gate electrode 165M may include at least one of a metal, a metal alloy, a conductive metal nitride, a metal silicide, a doped semiconductor material, a conductive metal oxide, and a conductive metal nitroxide.

The main gate insulation film 162M may extend along a side of the main gate electrode 165M. The main gate insulation film 162M may extend along a side of the gate spacer 164. The main gate insulation film 162M may include a variety of insulating materials.

In the implementation, the main gate insulation film 162M is illustrated as a single film but is not limited thereto. For example, the main gate insulation film 162M may be made of multiple films including silicon oxide (SiO₂) and a high dielectric constant material. In this case, the high dielectric constant material may include a material having a higher dielectric constant than silicon oxide (SiO₂), such as hafnium oxide (HfO), aluminum oxide (AlO), or tantalum oxide (TaO).

The semiconductor device according to the implementation may further include a gate spacer 164 and a capping layer 166.

The gate spacer 164 may be positioned on the side of the main gate electrode 165M. The gate spacer 164 may not be positioned between the active pattern 105 and the plurality of channel patterns 140. The gate spacer 164 may not be positioned between the plurality of channel patterns 140 adjacent in the third direction (Z direction).

The gate spacer 164 may include, for example, at least one of silicon nitride (SiN), silicon nitroxide (SiON), silicon oxide (SiO₂), silicon carbonate nitride (SiOCN), silicon boron nitride (SiBN), silicon oxyboron nitride (SiOBN), silicon oxycarbide (SiOC) and combinations thereof. Although the gate spacer 164 is illustrated as being a single film, it is only for convenience of description and is not limited thereto.

The capping layer 166 may be positioned on the main gate structure 160M and the gate spacer 164. A top surface of the capping layer 166 and a top surface of an interlayer insulation layer 190 may be placed on the same plane. Unlike the illustration, the capping layer 166 may be positioned between the gate spacers 164.

The capping layer 166 may include, for example, at least one of silicon nitride (SiN), silicon nitroxide (SiON), Silicon carbonitride (SiCN), silicon carbonate nitride (SiOCN), and combinations thereof. The capping layer 166 may include a material having an etch selectivity with respect to the interlayer insulation layer 190.

The source/drain patterns 300 will be described below with further reference to FIG. 5.

Referring further to FIG. 5, the source/drain patterns 300 may be positioned on at least one side of the gate structure 160. For example, the source/drain patterns 300 may be positioned on opposite sides of the gate structure 160. The source/drain patterns 300 may be positioned on the active pattern 105. The source/drain patterns 300 may be in contact with the sides of the plurality of channel patterns 140. The source/drain patterns 300 may be connected to the plurality of channel patterns 140.

The source/drain patterns 300 according to the implementation may include a lower source/drain pattern 300A and an upper source/drain pattern 300B.

The lower source/drain pattern 300A may be positioned on the active pattern 105. The lower source/drain pattern 300A may be positioned on at least one side of the lower gate structure 160A. For example, the lower source/drain pattern 300A may be positioned on opposite sides of the lower gate structure 160A. The lower source/drain patterns 300A may be connected with the plurality of lower channel patterns 140A.

The lower source/drain pattern 300A may be positioned within a lower source/drain trench 300AT extending along the third direction (Z direction). The lower source/drain pattern 300A may fill the lower source/drain trench 300AT. The lower source/drain trench 300AT may be positioned on opposite sides of the plurality of lower channel patterns 140A. The bottom surface of the lower source/drain trench 300AT may be defined by the active pattern 105. The sidewall of the lower source/drain trench 300AT may be defined by the plurality of lower channel patterns 140A, the plurality of lower gate structures 160A, and the middle dielectric isolation structure MDI. Accordingly, the lower source/drain pattern 300A may be in contact with the top surface of the active pattern 105 and the side of the plurality of lower channel patterns 140A, respectively.

The lower source/drain patterns 300A may be epitaxial patterns formed by a selective epitaxial growth process utilizing the active pattern 105 and the plurality of lower channel patterns 140A as seeds. The lower source/drain pattern 300A may serve as a source/drain for a first transistor structure utilizing the plurality of lower channel patterns 140A as channel regions. Here, the first transistor structure may be, but is not limited to, an N-type MOSFET.

As illustrated in FIG. 4, in a cross-section in the second direction (Y direction) and third direction (Z direction), the lower source/drain pattern 300A may have a trapezoidal shape that increases in width as it approaches the top surface of the substrate 101. That is, in a cross-section in the second direction (Y direction) and the third direction (Z direction), the lower source/drain pattern 300A may include an inclined surface that is inclined from the top surface of the substrate 101. This inclination may be due to the process characteristic in which the lower source/drain pattern 300A is formed within the space between the gate spacers 164 facing each other.

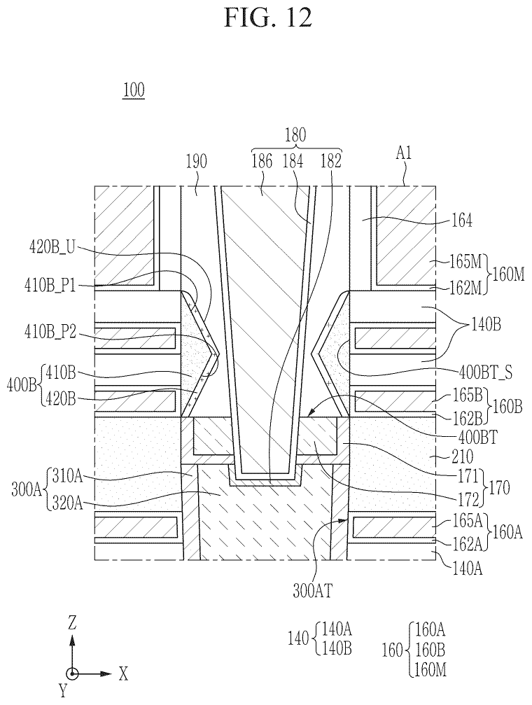

However, the present disclosure is not limited thereto, and in one example, the width along the second direction (Y direction) of the lower source/drain pattern 300A may be constant. In another example, the lower source/drain pattern 300A may further include a portion that protrudes toward the interlayer insulation layer 190. This will be described later with reference to FIG. 12.

In the implementation, as illustrated in FIG. 5, the top surface of the lower source/drain pattern 300A may be positioned at a higher level than the top surface of the topmost lower gate structure 160A. That is, the top surface of the lower source/drain pattern 300A may be positioned further from the top surface of the substrate 101 than the top surface of the topmost lower gate structure. In other words, the length along the third direction (Z direction) from the top surface of the substrate 101 to the top surface of the lower source/drain pattern 300A may be greater than the length along the third direction (Z direction) from the top surface of the substrate 101 to the top surface of the topmost lower gate structure. Accordingly, a portion of the side of the lower source/drain pattern 300A may be in contact with the middle dielectric isolation structure MDI. That is, the top surface of the lower source/drain pattern 300A may be positioned at a higher level than the bottom surface of the middle dielectric isolation structure MDI. The top surface of the lower source/drain pattern 300A may be positioned further from the top surface of the substrate 101 than the bottom surface of the middle dielectric isolation structure MDI. However, the present disclosure is not limited thereto, and the top surface of the lower source/drain pattern 300A may be positioned substantially at the same level as the top surface of the topmost lower gate structure 160A.

In the implementation, in the cross-section in the first direction (X direction) and the third direction (Z direction), the lower source/drain pattern 300A may have an inclined side such that the width of the lower portion is narrower than the width of the upper portion based on an aspect ratio but is not limited thereto. For example, a lower width and an upper width of the lower source/drain pattern 300A may be substantially the same.

The lower source/drain pattern 300A of the semiconductor device according to the implementation may include a first lower source/drain layer 310A and a second lower source/drain layer 320A.

The first lower source/drain layer 310A may be positioned along the inner sidewall and the bottom surface of the lower source/drain trench 300AT. A portion of the first lower source/drain layer 310A positioned along the inner sidewall of the lower source/drain trench 300AT may be in contact with the plurality of lower channel patterns 140A. A portion of the first lower source/drain layer 310A positioned along the bottom surface of the lower source/drain trench 300AT may be in contact with the active pattern 105. The first lower source/drain layer 310A may include a semiconductor material. For example, the first lower source/drain layer 310A may include a semiconductor material, such as silicon (Si) or silicon germanium (SiGe).

The second lower source/drain layer 320A may be positioned on the first lower source/drain layer 310A. The second lower source/drain layer 320A may fill the portion of the lower source/drain trench 300AT left after the first lower source/drain layer 310A was formed. The top surface of the second lower source/drain layer 320A may be positioned at the same level as the top surface of the first lower source/drain layer 310A. That is, the top surface of the lower source/drain pattern 300A may be defined by the top surface of the first lower source/drain layer 310A and the top surface of the second lower source/drain layer 320A.

The second lower source/drain layer 320A may include a semiconductor material. For example, the second lower source/drain layer 320A may include the same material as the first lower source/drain layer 310A. In one example, the first lower source/drain layer 310A and the second lower source/drain layer 320A may include a semiconductor material, such as silicon (Si) or silicon germanium (SiGe).

In the implementation, the first lower source/drain layer 310A and/or the second lower source/drain layer 320A may be doped with impurities. For example, when the first transistor structure is the n-type, the first lower source/drain layer 310A and/or the second lower source/drain layer 320A may include n-type impurities. In one example, the first lower source/drain layer 310A and the second lower source/drain layer 320A may include P, Sb, As, or a combination thereof. In this case, the material of the impurity contained in the first lower source/drain layer 310A may be different from the material of the impurity contained in the second lower source/drain layer 320A. Alternatively, the concentration of impurities doped in the first lower source/drain layer 310A may be different from the concentration of impurities doped in the second lower source/drain layer 320A. For example, the concentration of n-type impurities doped in the second lower source/drain layer 320A may be greater than the concentration of n-type impurities doped in the first lower source/drain layer 310A, but the present disclosure is not limited thereto. As another example, when the first transistor structure is the p-type, the second lower source/drain layer 320A may include p-type impurities.

While the second lower source/drain layer 320A may include the same material as the first lower source/drain layer 310A, the present disclosure is not limited thereto. For example, the second lower source/drain layer 320A may further include a material that is different from the material of the first lower source/drain layer 310A. For example, the second lower source/drain layer 320A may further include carbon (C), silicon (Si), germanium (Ge), or tin (Sn). In one example, the first lower source/drain layer 310A may include silicon (Si) and the second lower source/drain layer 320A may include silicon germanium (SiGe). In another example, the second lower source/drain layer 320A may include the same materials as the first lower source/drain layer 310A, and the concentrations of the constituent materials in the first lower source/drain layer 310A and the second lower source/drain layer 320A may be different. For example, when the first lower source/drain layer 310A and the second lower source/drain layer 320A include silicon germanium (SiGe), the concentration of germanium (Ge) in the first lower source/drain layer 310A may be less than the concentration of germanium (Ge) in the second lower source/drain layer 320A, but the present disclosure is not limited thereto. As another example, the second lower source/drain layer 320A may include the same material as the first lower source/drain layer 310A, and the first lower source/drain layer 310A and the second lower source/drain layer 320A may have the same concentration of constituent material.

In an implementation, the lower source/drain pattern 300A is described as having multiple layers but is not limited thereto. The lower source/drain pattern 300A may have a single layer including a semiconductor material.

The upper source/drain pattern 300B of the semiconductor device 100 according to the implementation may be positioned on the lower source/drain pattern 300A.

The upper source/drain pattern 300B may be spaced apart from the lower source/drain pattern 300A in the third direction (Z direction). For example, a barrier structure 170 may be positioned between the upper source/drain pattern 300B and the lower source/drain pattern 300A, and the upper source/drain pattern 300B and the lower source/drain pattern 300A may be spaced apart by the barrier structure 170. Accordingly, the upper source/drain pattern 300B and the lower source/drain pattern 300A may be electrically insulated.

The upper source/drain pattern 300B may be positioned on at least one side of the upper gate structure 160B. For example, the upper source/drain patterns 300B may be positioned on opposite sides of the upper gate structure 160B. The upper source/drain patterns 300B may be connected with the plurality of upper channel patterns 140B.

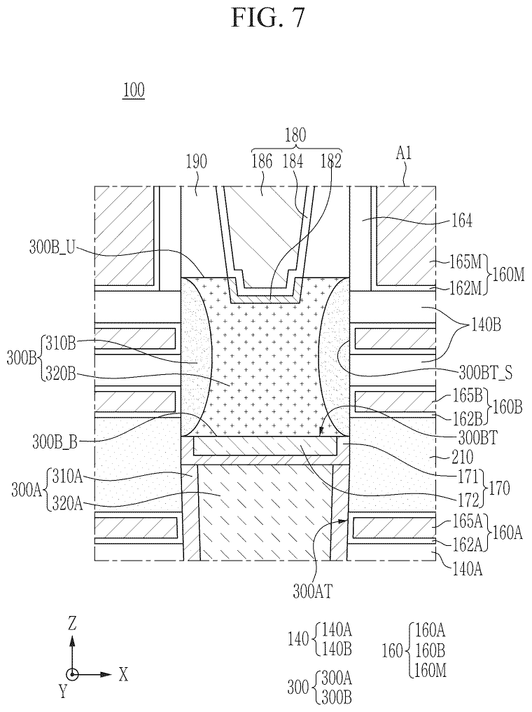

The upper source/drain pattern 300B may be positioned within an upper source/drain trench 300BT. The upper source/drain pattern 300B may fill the upper source/drain trench 300BT. The upper source/drain trench 300BT may be positioned on opposite sides of the plurality of upper channel patterns 140B. A bottom surface 300BT_B of the upper source/drain trench 300BT may be defined by the barrier structure 170 but is not limited thereto. A sidewall 300BT_S of the upper source/drain trench 300BT may be defined by the plurality of upper channel patterns 140B and the plurality of upper gate structures 160B. However, the present disclosure is not limited thereto, and the sidewall 300BT_S of the upper source/drain trench 300BT may be defined by the plurality of upper channel patterns 140B and the plurality of upper gate structures 160B, as well as by the middle dielectric isolation structure MDI and/or the gate spacers 164. These will be described hereinafter with reference to FIG. 7.

Accordingly, the upper source/drain pattern 300B may be in contact with the side of the plurality of upper channel patterns 140B. Also, unlike the lower source/drain pattern 300A, as the upper source/drain pattern 300B is spaced apart from the lower source/drain pattern 300A in the third direction (Z direction), the upper source/drain pattern 300B may not be in contact with the top surface of the active pattern 105.

The upper source/drain patterns 300B may be epitaxial patterns formed by a selective epitaxial growth process utilizing the plurality of upper channel patterns 140B as seeds. In this case, the upper source/drain pattern 300B may be a pattern formed by using opposite sides of the plurality of upper channel patterns 140B as seeds. That is, unlike the lower source/drain pattern 300A, which is the pattern formed using the top surface of the active pattern 105 and opposite sides of the plurality of lower channel patterns 140A as seeds, the upper source/drain pattern 300B may be a pattern formed using only opposite sides of the plurality of upper channel patterns 140B as seeds. The upper source/drain pattern 300B may serve as a source/drain for a second transistor structure utilizing the plurality of upper channel patterns 140B as channel regions. Here, the second transistor structure may be, but is not limited to, a P-type MOSFET.

As illustrated in FIG. 4, in the cross-section in the second direction (Y direction) and the third direction (Z direction), the upper source/drain pattern 300B may have a different shape from the lower source/drain pattern 300A. For example, in the cross-section in the second direction (Y direction) and the third direction (Z direction), the upper source/drain pattern 300B may have a hexagonal shape but is not limited thereto. In one example, the upper source/drain pattern 300B may have a circular, elliptical, or pentagonal shape, or shapes similar thereto. In the meantime, as described above, the lower source/drain pattern 300A may have a trapezoidal shape that increases in width as it approaches the top surface of the substrate 101. This may be due to a process characteristic in which the lower source/drain pattern 300A is formed within the space between the gate spacers 164 facing each other, while the upper source/drain pattern 300B is formed within the open space above the barrier structure 170.

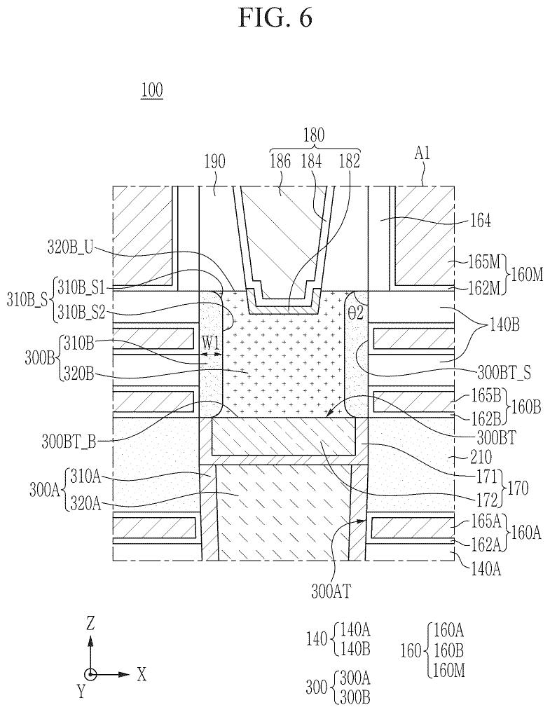

In the example illustrated in FIG. 5, the top surface of the upper source/drain pattern 300B may be positioned at substantially the same level as the top surface of the topmost upper channel pattern 140B. That is, the top surface of the upper source/drain pattern 300B may have a substantially same distance from the top surface of the topmost upper channel pattern 140B, and the top surface of the substrate 101. Additionally, the bottom surface of the upper source/drain pattern 300B may be positioned at substantially the same level as the top surface of the middle dielectric isolation structure MDI. The bottom surface of the upper source/drain pattern 300B may be positioned at substantially the same level as the bottom surface of the bottommost upper gate structure 160B. However, the present disclosure is not limited thereto, and the top surface of the upper source/drain pattern 300B may be positioned at a higher level than the top surface of the topmost upper channel pattern 140B. Additionally, a bottom surface of the upper source/drain pattern 300B may be positioned at a lower level than a bottom surface of the bottommost upper gate structure 160B. This will be described later with reference to FIG. 6 and below.

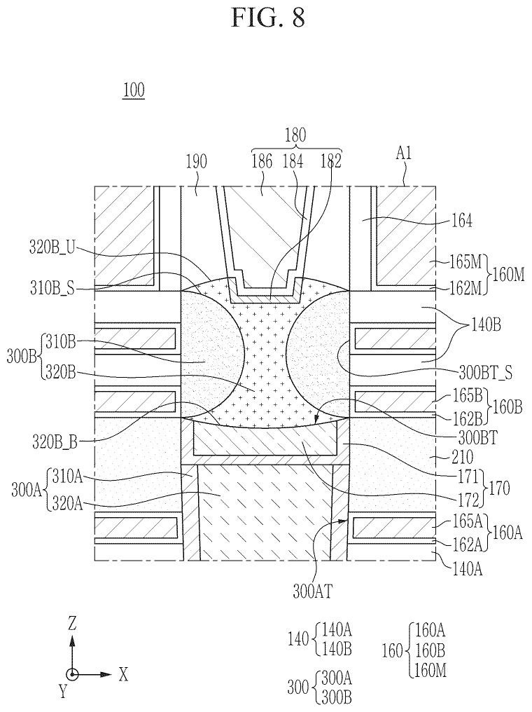

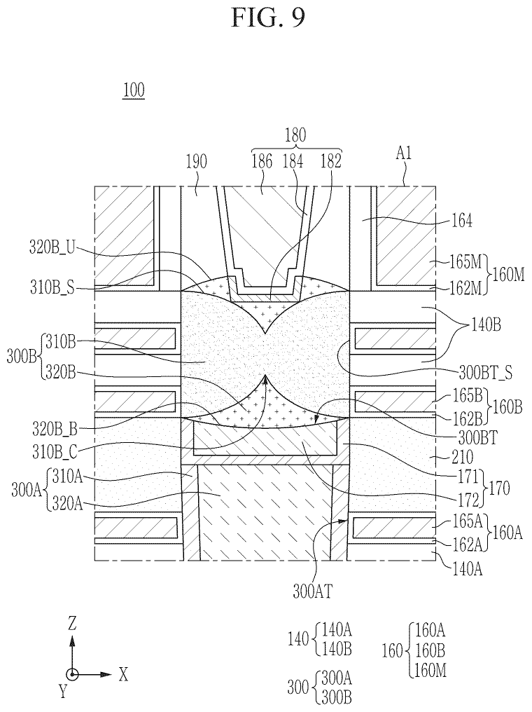

In the implementation, the top surface of the upper source/drain pattern 300B may include a flat portion. For example, the portion of the top surface of the upper source/drain pattern 300B that is in contact with the interlayer insulation layer 190 may be flat. That is, the top surface of the upper source/drain pattern 300B may include a portion that extends straight in the first direction (X direction). Additionally, the bottom surface of the upper source/drain pattern 300B may be flat. For example, the bottom surface of the upper source/drain pattern 300B that is in contact with the barrier structure 170 may extend straight in the first direction (X direction). However, the present disclosure is not limited thereto, and the top surface of the upper source/drain pattern 300B may have a convex shape toward a direction away from the substrate 101. Alternatively, the bottom surface of the upper source/drain pattern 300B may have a convex shape toward the substrate 101. This will be described later with reference to FIGS. 8 and 9.

In the implementation, a lower width and an upper width of the upper source/drain pattern 300B may be substantially equal but are not limited thereto. For example, the upper source/drain pattern 300B may have inclined sides such that the width of the lower portion is narrower than the width of the upper portion, depending on the aspect ratio.

The upper source/drain pattern 300B of the semiconductor device according to an implementation may include a first upper source/drain layer 310B and a second upper source/drain layer 320B.

The first upper source/drain layers 310B may be positioned on the sidewall 300BT_S of the upper source/drain trench 300BT. For example, the first upper source/drain layers 310B may be positioned on opposite sidewalls of the upper source/drain trench 300BT. The first upper source/drain layers 310B positioned along the sidewall 300BT_S of the upper source/drain trench 300BT may be in contact with the plurality of upper channel patterns 140B.

In an implementation, the first upper source/drain layers 310B may not cover at least a portion of the bottom surface 300BT_B of the upper source/drain trench 300BT. For example, the first upper source/drain layers 310B may not be positioned on the bottom surface 300BT_B of the upper source/drain trench 300BT. This may be due to the process characteristic in which the first upper source/drain layers 310B are formed using opposite sides of the plurality of upper channel patterns 140B as seeds. That is, unlike for the lower source/drain pattern 300A for which a pattern formed by using the top surface of the active pattern 105 and opposite sides of the plurality of lower channel patterns 140A as seeds, the upper source/drain pattern 300B may be a pattern formed by using only opposite sides of the plurality of upper channel patterns 140B as seeds. Accordingly, the first upper source/drain layers 310B may not cover at least a portion of the bottom surface 300BT_B of the upper source/drain trench 300BT.

In an implementation, the first upper source/drain layers 310B may be spaced apart in the first direction (X direction). For example, the first upper source/drain layers 310B positioned on one side of the upper source/drain trench 300BT and the first upper source/drain layers 310B positioned on the other side of the upper source/drain trench 300BT may be spaced apart in the first direction (X direction). Thus, a predetermined gap may occur between the first upper source/drain layers 310B. However, the present disclosure is not limited thereto, and, in some implementations, the first upper source/drain layers 310B may be in contact with each other. This will be discussed further with reference to FIG. 9.

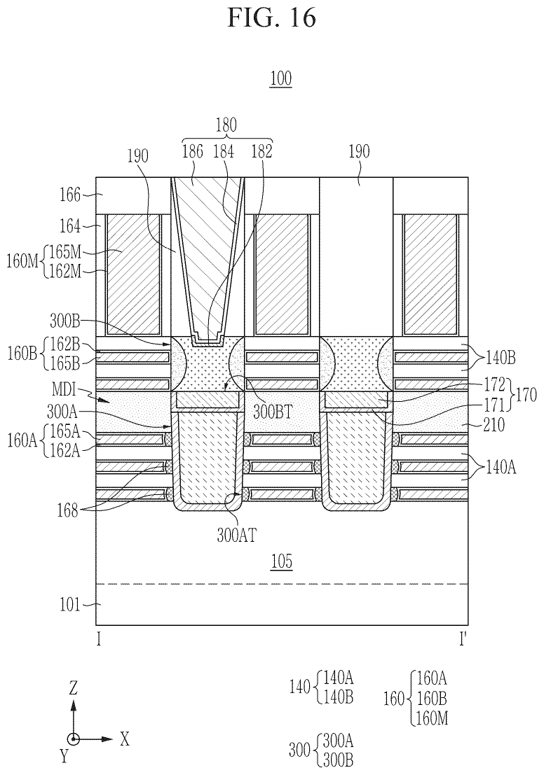

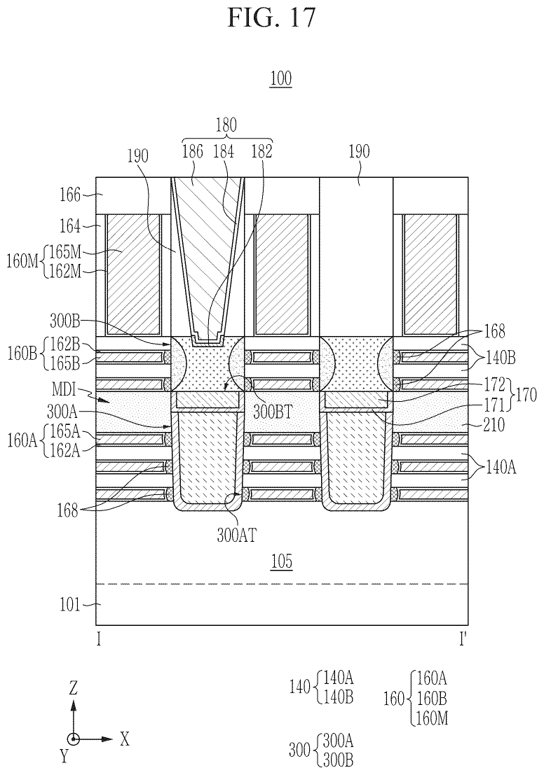

In an implementation, the first upper source/drain layers 310B may be in contact with the plurality of upper channel patterns 140B and the upper gate structure 160B. The first upper source/drain layers 310B may overlap the plurality of upper channel patterns 140B and the upper gate structure 160B in the first direction (X direction). In one example, an edge of the first upper source/drain layers 310B may be aligned with the top surface of the topmost upper channel pattern 140B. Additionally, the first upper source/drain layers 310B may non-overlap the middle dielectric isolation structure MDI and the gate spacer 164 in the first direction (X direction). However, the present disclosure is not limited thereto, and an inner gate spacer 168 may be further positioned between the first upper source/drain layers 310B and the upper gate structure 160B. Additionally, the first upper source/drain layers 310B may be in contact with the middle dielectric isolation structure MDI and/or the gate spacer 164. This will be described later with reference to FIGS. 16 and 17.

In an implementation, the first upper source/drain layers 310B may protrude from the sidewall 300BT_S of the upper source/drain trench 300BT. For example, the side 310B_S of the first upper source/drain layers 310B may have a convex shape from the sidewall 300BT_S of the upper source/drain trench 300BT. In one example, the side 310B_S of the first upper source/drain layers 310B may include a curved surface that is convex from the sidewall 300BT_S of the upper source/drain trench 300BT. For example, as illustrated in FIG. 5, the side 310B_S of the first upper source/drain layers 310B may have a rounded shape. This may be due to a process characteristic in which the first upper source/drain layers 310B are formed using opposite sides of the plurality of upper channel patterns 140B as seeds.

Accordingly, the width along the first direction (X direction) of the first upper source/drain layers 310B may gradually increase from the upper and lower portions of the upper source/drain trench 300BT toward the center portion. For example, a first width W1 along the first direction (X direction) at the center portion of the first upper source/drain layers 310B may be greater than a second width W2 along the first direction (X direction) at the upper portion of the first upper source/drain layers 310B. Further, the first width W1 along the first direction (X direction) of the center portion of the first upper source/drain layer 310B may be greater than a third width W3 along the first direction (X direction) of the lower portion of the first upper source/drain layer 310B. In this case, the first width W1 along the first direction (X direction) of the center portion of the first upper source/drain layer 310B may be a maximum width along the first direction (X direction) of the first upper source/drain layers 310B. In one example, the first width W1 along the first direction (X direction) of the center portion of the first upper source/drain layer 310B may be greater than about 0 nm and less than about 10 nm.

Further, a first angle θ1 formed by the side 310B_S of the first upper source/drain layers 310B and the sidewall 300BT_S of the upper source/drain trench 300BT may be from 0° to 90°. In one example, the first angle θ1 formed by the side 310B_S of the first upper source/drain layers 310B and the sidewall 300BT_S of the upper source/drain trench 300BT may be 80° to 90°. In this range, when the second upper source/drain layer 320B is formed between the first upper source/drain layers 310B, the second upper source/drain layer 320B may be formed to completely fill the upper source/drain trench 300BT.

In the implementation, the first upper source/drain layers 310B may have a symmetrical shape relative to an axis of symmetry parallel to the third direction (Z direction). For example, the first upper source/drain layer 310B positioned on the one sidewall 300BT_S of the upper source/drain trench 300BT and the first upper source/drain layer 310B positioned on the other sidewall 300BT_S of the upper source/drain trench 300BT may have a symmetrical shape relative to an axis of symmetry. Here, an axis of symmetry parallel to the third direction (Z direction) may refer to an axis that passes through the center portion of the upper source/drain trench 300BT and extends in a direction parallel to the third direction (Z direction).

In the implementation, at least one of the first upper source/drain layers 310B may have a maximum width in the first direction (X direction) above or below the center portion in the third direction (Z direction). Alternatively, the first upper source/drain layers 310B positioned on opposite sides of the upper source/drain pattern 310 may have different maximum widths.

While FIG. 5 illustrates that the side 310B_S of the first upper source/drain layers 310B is the curved surface, the present disclosure is not limited thereto, and the side 310B_S of the first upper source/drain layers 310B may vary to the extent that they have a convex shape from the sidewall 300BT_S of the upper source/drain trench 300BT. For example, the side 310B_S of the first upper source/drain layers 310B may further include a side extending in the third direction (Z direction). Alternatively, the side 310B_S of the first upper source/drain layers 310B may include a plurality of inclined surfaces. This will be described later with reference to FIGS. 6, 10, and 11.

The first upper source/drain layers 310B may include a semiconductor material. For example, the first upper source/drain layers 310B may include the semiconductor material, silicon (Si) or silicon germanium (SiGe).

In the implementation, the first upper source/drain layers 310B may include impurities. For example, if the second transistor structure is p-type, the first upper source/drain layers 310B may include p-type impurities. In one example, the first upper source/drain layers 310B may include B, V, In, Ga, Al, or a combination thereof.

The second upper source/drain layer 320B may be positioned between the first upper source/drain layers 310B.

The second upper source/drain layer 320B may fill in the portion left after the first upper source/drain layers 310B were formed in the upper source/drain trench 300BT. The second upper source/drain layer 320B may be positioned on the barrier structure 170 that defines the bottom surface 300BT_B of the upper source/drain trench 300BT. Accordingly, the second upper source/drain layer 320B may be spaced apart from the lower source/drain pattern 300A in the third direction (Z direction) by the barrier structure 170. The second upper source/drain layer 320B may be in contact with the sides 310B_S of the first upper source/drain layers 310B. Thus, the first upper source/drain layers 310B are positioned between the second upper source/drain layer 320B and the plurality of upper channel patterns 140B, the second upper source/drain layer 320B may be in non-contact with the plurality of upper channel patterns 140B, but the present disclosure is not limited to.

In the implementation, the second upper source/drain layer 320B may fill the portion left after the first upper source/drain layer 310B was formed in the upper source/drain trench 300BT. Accordingly, the side of the second upper source/drain layer 320B may have a complementary shape to the side of the first upper source/drain layer 310B. For example, the side 310B_S of the first upper source/drain layer 310B may have a convex shape (e.g., curved away) as looked at from the sidewall 300BT_S of the upper source/drain trench 300BT, and, corresondingly, the side of the second upper source/drain layer 320B may have a curved shape (e.g., concave) toward the center portion of the second upper source/drain layer 320B.

Accordingly, the width along the first direction (X direction) of the second upper source/drain layer 320B may gradually decrease from the upper and lower portions of the upper source/drain trench 300BT toward the center portion. For example, a fourth width W4 along the first direction (X direction) of the center portion of the second upper source/drain layer 320B may be smaller than the width along the first direction (X direction) of the upper portion of the second upper source/drain layer 320B. Furthermore, the fourth width W4 along the first direction (X direction) of the center portion of the second upper source/drain layer 320B may be smaller than the width along the first direction (X direction) of the lower portion of the second upper source/drain layer 320B. In this case, the fourth width W4 along the first direction (X direction) of the center portion of the second upper source/drain layer 320B may be a minimum width along the first direction (X direction) of the second upper source/drain layer 320B. In one example, the fourth width W4 along the first direction (X direction) of the center portion of the second upper source/drain layer 320B may be greater than about 5 nm and less than about 25 nm.

In the implementation, a top surface 320B_U of the second upper source/drain layer 320B may be positioned at the same level as the top surface of the topmost upper channel pattern 140B among the plurality of upper channel patterns 140B. That is, the distance from the top surface of the substrate 101 to the top surface 320B_U of the second upper source/drain layer 320B may be substantially the same as the distance from the top surface of the substrate 101 to the top surface of the topmost upper channel pattern 140B among the plurality of upper channel patterns 140B. Accordingly, the second upper source/drain layer 320B may not overlap the main gate structure 160M in the first direction (X direction). Further, the top surface 320B_U of the second upper source/drain layer 320B may be aligned with edges of the first upper source/drain layer 310B. However, the present disclosure is not limited thereto, and the top surface 320B_U of the second upper source/drain layer 320B may be positioned at a higher level than the top surface of the topmost upper channel pattern 140B among the plurality of upper channel patterns 140B. This will be described later with reference to FIG. 7.

In the implementation, the top surface 320B_U of the second upper source/drain layer 320B may include a flat portion. For example, the portion of the top surface 320B_U of the second upper source/drain layer 320B that is in contact with the interlayer insulation layer 190 may be flat

That is, the top surface 320B_U of the second upper source/drain layer 320B may include a portion that extends straight in the first direction (X direction). Additionally, the bottom surface of the second upper source/drain layer 320B may be flat. For example, the bottom surface of the second upper source/drain layer 320B that is in contact with the barrier structure 170 may extend straight in the first direction (X direction). However, the present disclosure is not limited thereto, and the top surface 320B_U of the second upper source/drain layer 320B may have a convex shape toward a direction away from the substrate 101. Alternatively, the bottom surface of the second upper source/drain layer 320B may have a convex shape toward the substrate 101. This will be described later with reference to FIGS. 8 and 9.

The second upper source/drain layer 320B may include a semiconductor material. For example, the second upper source/drain layer 320B may include the same material as the first upper source/drain layer 310B. In one example, the first upper source/drain layer 310B and the second upper source/drain layer 320B may include a semiconductor material, such as silicon (Si) or silicon germanium (SiGe).

In this case, the concentrations of the constituent materials of the first upper source/drain layer 310B and the second upper source/drain layer 320B may be different. For example, when the first upper source/drain layers 310B and the second upper source/drain layer 320B include silicon germanium (SiGe), the concentration of germanium (Ge) in the second upper source/drain layer 320B may be greater than the concentration of germanium (Ge) in the first upper source/drain layer 310B. In one example, the germanium (Ge) concentration in the second upper source/drain layer 320B may be equal to or greater than 60 at % and less than 70 at %, but the present disclosure is not limited thereto. In this range, when the second upper source/drain layer 320B is formed between the first upper source/drain layers 310B, the second upper source/drain layer 320B may include portions of the top surface 320B_U and the bottom surface that are flat. However, the present disclosure is not limited thereto, and the germanium (Ge) concentration of the second upper source/drain layer 320B may be less than 60 at %. This will be described below with reference to FIGS. 8 and 9.

In an implementation, the first upper source/drain layers 310B and/or the second upper source/drain layers 320B may be doped with impurities. For example, when the first transistor structure is p-type, the first upper source/drain layers 310B and/or the second upper source/drain layers 320B may include p-type impurities. In one example, the first upper source/drain layer 310B and the second upper source/drain layer 320B may include B, C, In, Ga, Al, or a combination thereof. In this case, the material of the impurity contained in the first upper source/drain layer 310B may be different from the material of the impurity contained in the second upper source/drain layer 320B. Alternatively, the concentration of the impurity doped in the first upper source/drain layer 310B may be different from the concentration of the impurity doped in the second upper source/drain layer 320B. In this case, the concentration of p-type impurities doped in the second upper source/drain layer 320B may be less than the concentration of p-type impurities doped in the first upper source/drain layer 310B, but the present disclosure is not limited thereto.

Although it is described that in the implementation, the second upper source/drain layer 320B includes the same material as the first upper source/drain layer 310B, the present disclosure is not limited thereto. For example, the second upper source/drain layer 320B may further include a material that is different from the material of the first upper source/drain layer 310B. For example, the second upper source/drain layer 320B may further include carbon (C), silicon (Si), germanium (Ge), or tin (Sn). In one example, the first upper source/drain layer 310B may include silicon (Si) and the second upper source/drain layer 320B may include silicon germanium (SiGe). As another example, the second upper source/drain layer 320B may include the same material as the first upper source/drain layer 310B, and the first upper source/drain layer 310B and the second upper source/drain layer 320B may have the same concentration of the constituent material.

In the implementation, the upper source/drain pattern 300B is described as including the first upper source/drain layer 310B and the second upper source/drain layer 320B, but the present disclosure is not limited thereto. For example, the upper source/drain pattern 300B may be divided into three or more layers.

In the process of forming the upper source/drain pattern 300B of the semiconductor device 100 according to the implementation, opposite sides of the plurality of upper channel patterns 140B may be utilized as seeds to form the first upper source/drain layers 310B. That is, unlike the lower source/drain pattern 300A, which is a pattern formed using the top surface of the active pattern 105 and opposite sides of the plurality of lower channel patterns 140A as seeds, the upper source/drain pattern 300B may be a pattern formed using only opposite sides of the plurality of upper channel patterns 140B as seeds. Accordingly, the first upper source/drain layers 310B may not cover at least a portion of the bottom surface 300BT_B of the upper source/drain trench 300BT.

Furthermore, the first upper source/drain layer 310B of the semiconductor device 100 according to the implementation has a convex shape from the sidewall 300BT_S of the upper source/drain trench 300BT, the second upper source/drain layer 320B may be stably formed in the space between the first upper source/drain layers 310B. Accordingly, the proportion of the second upper source/drain layer 320B formed within the upper source/drain trench 300BT may be increased.

The barrier structure 170 may be positioned between the lower source/drain pattern 300A and the upper source/drain pattern 300B. The barrier structure 170 may overlap the lower source/drain pattern 300A and the upper source/drain pattern 300B in the third direction (Z direction). The barrier structure 170 may be positioned between the middle dielectric isolation structures MDIs. The top surface and the bottom surface of the barrier structure 170 may be flat, but are not limited thereto. For example, the top surface and/or the bottom surface of the barrier structure 170 may have an upwardly convex or downwardly convex shape.

The barrier structure 170 may include a first barrier pattern 171 extending along the side of the middle dielectric isolation structure MDI and the top surface of the lower source/drain pattern 300A, and a second barrier pattern 172 positioned on the first barrier pattern 171. The first barrier pattern 171 may be positioned on the side of the gate spacer 164, as illustrated in FIG. 4 but is not limited thereto. For example, the first barrier pattern 171 may not be positioned on the side of the gate spacer 164.

The first and second barrier patterns 171 and 172 may include various insulating materials. The first barrier pattern 171 and the second barrier pattern 172 may include different materials, but are not limited thereto. For example, the first barrier pattern 171 may include silicon nitride, silicon nitroxide, or a combination thereof, and the second barrier pattern 172 may include silicon oxide, silicon nitride, silicon nitroxide, or a combination thereof. The barrier structure 170 may space the lower source/drain pattern 300A and the upper source/drain pattern 300B from each other in the third direction (Z direction).

The semiconductor device may further include the interlayer insulation layer 190.

The interlayer insulation layer 190 may be positioned on the side of the gate spacer 164, the side of the capping layer 166, and the top surface of the upper source/drain pattern 300B. The interlayer insulation layer 190 may not cover the top surface of the capping layer 166.

The interlayer insulation layer 190 may include at least one of, for example, silicon oxide (SiO₂), silicon nitride (SiN), silicon nitroxide (SiON), and a low dielectric constant material. The low dielectric constant material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), DiAcetoSDitertiane (TMSB), DiAcetoxyDitertiaryButoSiloxane (DADBS), TriMethylSilil Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped Silicon Oxide (CDO), Organo Silicate Glass (OSG), SiLK, Amorphous Fluorinated Carbon, silica aerogels, silica xerogels, mesoporous silica, or combinations thereof but is not limited thereto.

In the implementation, although not illustrated, an etch stop film may be further positioned between the gate spacer 164 and the interlayer insulation layer 190 and between the upper source/drain pattern 300B and the interlayer insulation layer 190. The etch stop film may include a material having an etch selectivity with respect to the interlayer insulation layer 190. The etch stop film 185 may include at least one of, for example, silicon nitride (SiN), silicon nitroxide (SiON), silicon carbonate nitride (SiOCN), silicon boron nitride (SiBN), silicon oxyboron nitride (SiOBN), silicon carbonate (SiOC), and combinations thereof.

The semiconductor device may further include a contact structure 180.

The contact structure 180 may be positioned on the upper source/drain pattern 300B. The contact structure 180 may be electrically connected to the upper source/drain pattern 300B through the interlayer insulation layer 190. The contact structure 180 may have an inclined side of which a lower width is narrower than an upper width based on an aspect ratio, but is not limited to. The contact structure 180 may be positioned to recess the upper source/drain pattern 300B to a predetermined depth.

For example, a bottom surface of the contact structure 180 may be higher than a bottom surface of the topmost channel pattern among the plurality of upper channel patterns 140B. However, the present disclosure is not limited thereto, and the bottom surface of the contact structure 180 may be positioned at a similar level to the bottom surface of the topmost upper channel pattern 140B among the plurality of upper channel patterns 140B, or may be lower than the bottom surface of the topmost channel pattern. Alternatively, the bottom surface of the contact structure 180 may be positioned between the bottom surface of the bottommost upper channel pattern among the plurality of upper channel patterns 140B and the bottom surface of the topmost upper channel pattern.

The contact structure 180 of the semiconductor device 100 according to the implementation may include a contact electrode 186, a first barrier layer 184 surrounding the contact electrode 186, and a first silicide film 182 positioned between the first barrier layer 184 and the upper source/drain pattern 300B.

The contact electrode 186 may include, for example, at least one of a metal, a metal alloy, a conductive metal nitride, a conductive metal carbide, a conductive metal oxide, a conductive metal carbonitride, and a two-dimensional (2D) material. The first barrier layer 184 may include, for example, a metal nitride, such as, titanium nitride (TiN), tantalum nitride (TaN), or tungsten nitride (WN).

The first silicide film 182 may surround a portion of the contact electrode 186 that is recessed into the upper source/drain pattern 300B. The first silicide film 182 may include a metal-silicide. For example, the first silicide film 182 may include at least one of titanium-silicide, tantalum-silicide, tungsten-silicide, nickel-silicide, and cobalt-silicide. In implementations, the number and arrangement of the conductive layers configuring the contact structure 180 may be varied. In some implementations, the first barrier layer 184 and/or the first silicide film 182 may be omitted.

It has been described above that the lower source/drain pattern 300A is positioned on the substrate 101, the upper source/drain pattern 300B positioned on the lower source/drain pattern 300A, and the upper source/drain pattern 300B includes the first upper source/drain layers 310B positioned on the side of the plurality of upper channel patterns 140B and the second upper source/drain layer 320B positioned between the first upper source/drain layers 310B. However, the present disclosure is not limited thereto, and even encompasses a semiconductor device 100 without a lower source/drain pattern 300A, so long as the upper source/drain pattern 300B is formed spaced apart from the substrate 101.

In the process of forming the upper source/drain pattern 300B of the semiconductor device 100 according to the implementation, opposite sides of the plurality of upper channel patterns 140B may be used as seeds to form the first upper source/drain layers 310B. That is, unlike the lower source/drain pattern 300A, which is a pattern formed using the top surface of the active pattern 105 and opposite sides of the plurality of lower channel patterns 140A as seeds, the first upper source/drain layer 310B may be a pattern formed using only opposite sides of the plurality of upper channel patterns 140B as seeds. Accordingly, the first upper source/drain layers 310B may not cover at least a portion of the bottom surface 300BT_B of the upper source/drain trench 300BT.

Furthermore, since the first upper source/drain layer 310B of the semiconductor device 100 according to the implementation has the convex shape from the sidewall 300BT_S of the upper source/drain trench 300BT, the second upper source/drain layer 320B may be stably formed within the space between the first upper source/drain layers 310B. That is, the second upper source/drain layer 320B may be completely filled within the upper source/drain trench 300BT. Accordingly, the proportion of the second upper source/drain layer 320B formed within the upper source/drain trench 300BT may be increased, and thus the reliability of the semiconductor device 100 may be improved.

Hereinafter, the upper source/drain pattern of the semiconductor device will be described with further reference to FIGS. 6 to 12.

FIG. 6 is a cross-sectional view corresponding to region A1 of FIG. 2, illustrating a semiconductor device.

The example illustrated in FIG. 6 is substantially identical to the example illustrated in FIGS. 1 to 5, and therefore like items will not be described but will be described in terms of differences. In the present implementation, the shape of the first upper source/drain layers 310B differs from the previous implementationas will be described below.

The side of the first upper source/drain layer 310B according to the implementation may include a first side 310B_S1 that is convex from the sidewall 300BT_S of the upper source/drain trench 300BT and a second side 310B_S2 that extends in the third direction (Z direction).

The first side 310B_S1 of the first upper source/drain layers 310B may extend from the sidewall 300BT_S of the upper source/drain trench 300BT. The first side 310B_S1 of the first upper source/drain layer 310B may have a rounded shape. The second angle θ2 formed by the first side 310B_S1 of the first upper source/drain layers 310B and the sidewall 300BT_S of the upper source/drain trench 300BT may be 80° to 90°. In this range, when the second upper source/drain layer 320B is formed between the first upper source/drain layers 310B, the second upper source/drain layer 320B may be formed to completely fill the upper source/drain trench 300BT. Further, the second upper source/drain layer 320B may be formed so that the top surface 320B_U of the second upper source/drain layer 320B includes a flat portion.

In the implementation, the first side 310B_S1 of the first upper source/drain layers 310B may form a portion of the top surface of the upper source/drain pattern 300B. In this case, the first side 310B_S1 of the first upper source/drain layer 310B and the top surface 320B_U of the second upper source/drain layer 320B may be positioned at the same level. That is, the first side 310B_S1 of the first upper source/drain layer 310B and the top surface 320B_U of the second upper source/drain layer 320B may be positioned at the same distance from the top surface of the substrate 101. The first side 310B_S1 of the first upper source/drain layer 310B may be in contact with the interlayer insulation layer 190. However, the present disclosure is not limited thereto, and the first side 310B_S1 of the first upper source/drain layer 310B may be surrounded by the second upper source/drain layer 320B.

The second side 310B_S2 of the first upper source/drain layer 310B may extend straight in the third direction (Z direction) from one side of the first side 310B_S1 of the first upper source/drain layer 310B. For example, a side of the center portion of the first upper source/drain layer 310B may extend in the third direction (Z direction). In this case, the first upper source/drain layer 310B may also have a shape that protrudes from the sidewall 300BT_S of the upper source/drain trench 300BT due to the first side 310B_S1. In other words, the side of the first upper source/drain layer 310B may have a shape that is convex from the sidewall 300BT_S of the upper source/drain trench 300BT.

In the implementation, the first width W1 along the first direction (X direction) of the center portion of the first upper source/drain layer 310B may be greater than a width of a top portion of the first upper source/drain layer 310B along the first direction (X direction) and a width of a bottom portion of the first upper source/drain layer 310B along the first direction (X direction). In one example, the first width W1 along the first direction (X direction) of the center portion of the first upper source/drain layer 310B may be greater than about 0 nm and less than about 10 nm. Here, the first width W1 along the first direction (X direction) of the center portion of the first upper source/drain layer 310B may be a maximum width of the first upper source/drain layer 310B along the first direction (X direction).

The second upper source/drain layer 320B may be positioned between the first upper source/drain layers 310B. The second upper source/drain layer 320B may fill the portion left after the first upper source/drain layers 310B was formed in the upper source/drain trench 300BT.

Accordingly, the sides of the second upper source/drain layer 320B may have a complementary shape to the sides of the first upper source/drain layers 310B. For example, the side of the first upper source/drain layer 310B may include a first side 310B_S1 that is convex from the opposite sidewall 300BT_S of the upper source/drain trench 300BT and a second side 310B_S2 that extends in a third direction (Z direction), and the side of the second upper source/drain layer 320B may conform to the side of the first upper source/drain layer and include a portion concave toward the center portion of the second upper source/drain layer 320B and a portion extending in the third direction (Z direction).

The first upper source/drain layer 310B of the semiconductor device 100 according to the implementation further includes the second side 310B_S2 extending in the third direction (Z direction), so that the proportion of the second upper source/drain layer 320B to the upper source/drain pattern 300B may be increased. That is, the ratio of the volume occupied by the second upper source/drain layer 320B to the volume of the upper source/drain trench 300BT may be increased. Accordingly, the reliability of the semiconductor device 100 may be improved.

FIG. 7 is a cross-sectional view corresponding to region A1 of FIG. 2, illustrating a semiconductor device.

The implementation illustrated in FIG. 7 is substantially identical to the implementation illustrated in FIGS. 1 to 5, and therefore will be described only in terms of differences from the earlier figures.

In the present implementation, the shape of the upper source/drain pattern 300B differs from the previous implementation, and will be described below.

A top surface 300B_U of the upper source/drain pattern 300B according to the implementation may be positioned at a higher level than the top surface of the topmost upper channel pattern 140B. That is, the top surface 300B_U of the upper source/drain pattern 300B may be positioned farther from the top surface of the substrate 101 than the top surface of the topmost upper channel pattern 140B. In other words, the top surface 300B_U of the upper source/drain pattern 300B may be positioned at a higher level than the bottom surface of the main gate structure 160M. Accordingly, the upper source/drain pattern 300B may overlap the plurality of upper channel patterns 140B and the upper gate structure 160B, as well as the main gate structure 160M and the gate spacer 164, in the first direction (X direction). The upper source/drain pattern 300B may be in contact with the gate spacer 164 but is not limited thereto.

Further, a bottom surface 300B_B of the upper source/drain pattern 300B according to the implementation may be positioned at a lower level than the top surface of the middle dielectric isolation structure MDI. The bottom surface 300B_B of the upper source/drain pattern 300B may be positioned at a lower level than the bottom surface of the bottommost upper gate structure 160B. That is, the bottom surface 300B_B of the upper source/drain pattern 300B may be positioned closer to the top surface of the substrate 101 than the top surface of the middle dielectric isolation structure MDI. Accordingly, the upper source/drain pattern 300B may overlap the plurality of upper channel patterns 140B and the upper gate structure 160B, as well as the middle dielectric isolation structure MDI, in the first direction (X direction). The upper source/drain pattern 300B may be in contact with the middle dielectric isolation structure MDI but is not limited thereto.

In FIG. 7, it is illustrated that the top surface 300B_U of the upper source/drain pattern 300B may be positioned at a higher level than the top surface of the topmost upper channel pattern 140B, and the bottom surface 300B_B of the upper source/drain pattern 300B may be positioned at a lower level than the top surface of the middle dielectric isolation structure MDI, but the present disclosure is not limited thereto. For example, the top surface 300B_U of the upper source/drain pattern 300B may be positioned at a higher level than the top surface of the topmost upper channel pattern 140B, and the bottom surface 300B_B of the upper source/drain pattern 300B may be positioned at substantially the same level as the top surface of the middle dielectric isolation structure MDI. Alternatively, the top surface 300B_U of the upper source/drain pattern 300B may be positioned at substantially the same level as the top surface of the topmost upper channel pattern 140B, and the bottom surface 300B_B of the upper source/drain pattern 300B may be positioned at a lower level than the top surface of the middle dielectric isolation structure MDI.

FIGS. 8 and 9 are cross-sectional views corresponding to region A1 of FIG. 2, illustrating a semiconductor device according to some implementations.

The implementations illustrated in FIGS. 8 and 9 are substantially identical to the implementation illustrated in FIGS. 1 to 5, and therefore will not be described but will be described in terms of differences. In the present implementation, the shape of the second upper source/drain layers 320B differs from the previous implementation, and will be described below.

The top surface 320B_U of the second upper source/drain layer 320B according to the implementation may include a convex shape in the direction away from the top surface of the substrate 101. For example, a portion of the top surface 320B_U of the second upper source/drain layer 320B that is in contact with the interlayer insulation layer 190 may be convex in the direction away from the top surface of the substrate 101. Accordingly, the second upper source/drain layer 320B may protrude from the top surface of the topmost upper channel pattern 140B. The second upper source/drain layer 320B may overlap the main gate structure 160M and the gate spacer 164 in the first direction (X direction).

Additionally, the bottom surface 320B_B of the second upper source/drain layer 320B according to the implementation may include a convex shape in the direction facing the substrate 101. For example, the bottom surface 320B_B of the second upper source/drain layer 320B that is in contact with the barrier structure 170 may be convex in the direction facing the substrate 101. Accordingly, the second upper source/drain layer 320B may protrude downwardly from the bottom surface of the bottommost upper gate structure 160B. The second upper source/drain layer 320B may overlap the middle dielectric isolation structure MDI in the first direction (X direction).

In the implementation, the second upper source/drain layer 320B may include a semiconductor material. For example, the second upper source/drain layer 320B may include the same material as the first upper source/drain layer 310B. In one example, the first upper source/drain layer 310B and the second upper source/drain layer 320B may include a semiconductor material, silicon (Si) or silicon germanium (SiGe).

In this case, the concentrations of the constituent materials of the first upper source/drain layer 310B and the second upper source/drain layer 320B may be different. For example, when the first upper source/drain layer 310B and the second upper source/drain layer 320B include silicon germanium (SiGe), the concentration of germanium (Ge) in the second upper source/drain layer 320B may be greater than the concentration of germanium (Ge) in the first upper source/drain layer 310B. In one example, the germanium (Ge) concentration in the second upper source/drain layer 320B may be equal to or greater than 50 at % and less than 60 at % but is not limited thereto. In this range, when the second upper source/drain layer 320B is formed between the first upper source/drain layers 310B, the top surface 320B_U and bottom surface 320B_B of the second upper source/drain layer 320B may have a convex shape.

In the implementation, the side 310B_S of the first upper source/drain layer 310B may have a convex shape from the sidewall 300BT_S of the upper source/drain trench 300BT. For example, the side 310B_S of the first upper source/drain layer 310B may have a rounded shape. In one example, a width of a center portion of the first upper source/drain layers 310B along the first direction (X direction) may be greater than a width of a top portion of the first upper source/drain layer 310B along the first direction (X direction) and a width of a bottom portion of the first upper source/drain layers 310B along the first direction (X direction).

On the other hand, when the top surface 320B_U and/or the bottom surface 320B_B of the second upper source/drain layer 320B has a convex shape, the width of the center portion of the first upper source/drain layer 310B along the first direction (X direction) may be equal to or greater than 10 nm or equal to or less than 13 nm or less. Here, the width of the center portion of the first upper source/drain layer 310B along the first direction (X direction) may be a maximum width of the first upper source/drain layer 310B along the first direction (X direction). Accordingly, the first upper source/drain layers 310B may be spaced apart or in contact with each other in the first direction (X direction).

For example, as illustrated in FIG. 8, the maximum width of the first upper source/drain layer 310B along the first direction (X direction) may be less than half the width of the upper source/drain trench 300BT along the first direction (X direction). Accordingly, the first upper source/drain layers 310B may be spaced apart in the first direction (X direction). In one example, the first upper source/drain layer 310B positioned on the one sidewall 300BT_S of the upper source/drain trench 300BT and the first upper source/drain layer 310B positioned on the other sidewall 300BT_S of the upper source/drain trench 300BT may be spaced apart in the first direction (X direction). In the implementation, a maximum width along the first direction (X direction) of the first upper source/drain layers 310B may be greater than a minimum separation distance between the first upper source/drain layers 310B along the first direction (X direction). That is, the maximum width of the first upper source/drain layer 310B along the first direction (X direction) may be greater than the minimum width of the second upper source/drain layer 320B along the first direction (X direction).

Alternatively, the first upper source/drain layers 310B may be in contact with each other, as illustrated in FIG. 9. For example, the first upper source/drain layer 310B positioned on the one sidewall 300BT_S of the upper source/drain trench 300BT and the first upper source/drain layer 310B positioned on the other sidewall 300BT_S of the upper source/drain trench 300BT may be in contact with each other. Accordingly, the first upper source/drain layer 310B may include a depression 310B_C that is recessed in the third direction (Z direction) from the center portion of the upper source/drain pattern 300B.

The depression 310B_C may be a portion where the side of the first upper source/drain layer 310B positioned on the one sidewall 300BT_S of the upper source/drain trench 300BT meets the side of the first upper source/drain layer 310B positioned on the other sidewall 300BT_S of the upper source/drain trench 300BT. The depression 310B_C may be positioned in the center portion of the upper source/drain pattern 300B. The depression 310B_C may have a rounded shape toward the center portion of the upper source/drain pattern 300B.

In FIGS. 8 and 9, it is illustrated that the top surface 320B_U and the bottom surface 320B_B of the second upper source/drain layer 320B have a convex shape, but the present disclosure is not limited thereto. For example, at least one of the top surface 320B_U and the bottom surface 320B_B of the second upper source/drain layer 320B may have a convex shape. Further, as illustrated in the implementation of FIG. 7, the top surface 300B_U of the upper source/drain pattern 300B may be positioned at a higher level than the top surface of the topmost upper channel pattern 140B, and the bottom surface 300B_B of the upper source/drain pattern 300B may be positioned at a lower level than the top surface of the middle dielectric isolation structure MDI. As another example, the top surface 300B_U of the upper source/drain pattern 300B may be positioned at a higher level than the top surface of the topmost upper channel pattern 140B, and the bottom surface 300B_B of the upper source/drain pattern 300B may be positioned at substantially the same level as the top surface of the middle dielectric isolation structure MDI. In another example, the top surface 300B_U of the upper source/drain pattern 300B may be positioned at substantially the same level as the top surface of the topmost upper channel pattern 140B, and the bottom surface 300B_B of the upper source/drain pattern 300B may be positioned at a lower level than the top surface of the middle dielectric isolation structure MDI.

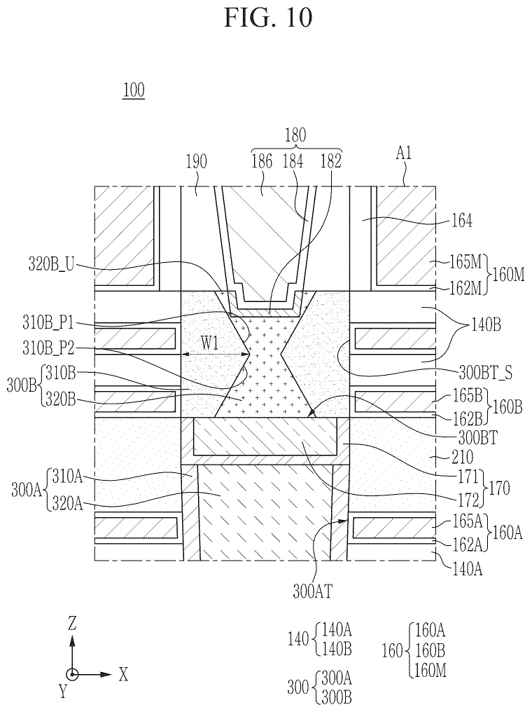

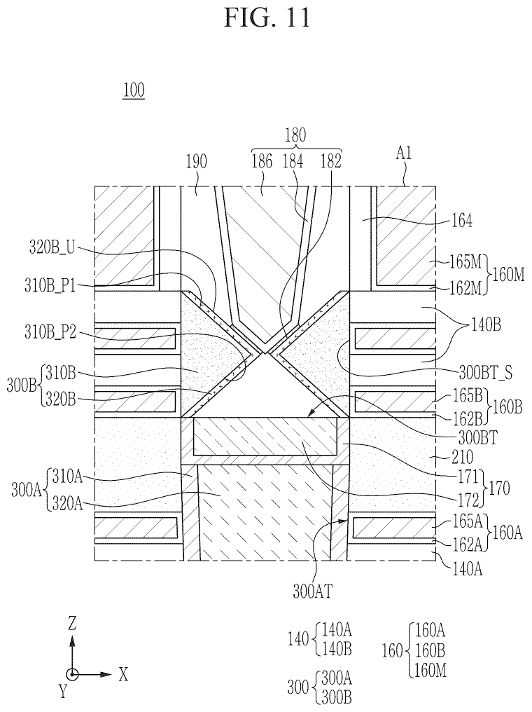

FIGS. 10 and 11 are cross-sectional views corresponding to region A1 of FIG. 2, illustrating a semiconductor device.

The implementations illustrated in FIGS. 10 and 11 are substantially identical to the implementation illustrated in FIGS. 1 to 5, and therefore will be described in terms of differences

In the present implementation, the shape of the upper source/drain pattern 300B differs from the previous implementation, and will be described below.

The side 310B_S of the first upper source/drain layers 310B may include a plurality of inclined surfaces that are inclined at a predetermined angle from the top surface of the substrate 101. For example, the first upper source/drain layer 310B may include a first inclined surface 310B_P1 that narrows in width along the first direction (X direction) as it goes away from the top surface of the substrate 101, and a second inclined surface 310B_P2 that widens in width along the first direction (X direction) as it goes away from the top surface of the substrate 101.

In the implementation, the first inclined surface 310B_P1 and the second inclined surface 310B_P2 of the first upper source/drain layer 310B may have different inclinations. For example, the first inclined surface 310B_P1 of the first upper source/drain layer 310B may be a side that is inclined at a predetermined angle from the top surface of the substrate 101 in one direction. Additionally, the second inclined surface 310B_P2 of the first upper source/drain layer 310B may be a side that is inclined at a predetermined angle from the top surface of the substrate 101 in the different direction.

Accordingly, the width along the first direction (X direction) of the first upper source/drain layers 310B may gradually increase from the upper and lower portions of the upper source/drain trench 300BT toward the center portion. In one example, the first width W1 of the center portion of the first upper source/drain layer 310B along the first direction (X direction) may be greater than a width of a top portion of the first upper source/drain layer 310B along the first direction (X direction) and a width of a bottom portion of the first upper source/drain layer 310B along a first direction (X direction). That is, the side 310B_S of the first upper source/drain layer 310B may have a convex shape from the sidewall 300BT_S of the upper source/drain trench 300BT. In one example, the first width W1 of the center portion of the first upper source/drain layer 310B along the first direction (X direction) may be equal to or greater than about 10 nm, and less than about 13 nm. In this range, the first upper source/drain layers 310B may include a plurality of inclined surfaces. Here, the first width W1 of the center portion of the first upper source/drain layer 310B along the first direction (X direction) may be a maximum width of the first upper source/drain layer 310B along the first direction (X direction). That is, according to the implementation, the first width W1 may mean a width of the portion where the first inclined surface 310B_P1 of the first upper source/drain layer 310B and the second inclined surface 310B_P2 of the first upper source/drain layer 310B meet along the first direction (X direction). The remainder of the description of the first upper source/drain layers 310B is substantially the same as the description of the first upper source/drain layers 310B of the implementation of FIGS. 1 to 5, and will therefore be omitted.

In the implementation, the second upper source/drain layer 320B may be positioned between the first upper source/drain layers 310B. The second upper source/drain layer 320B may fill the portion left after the first upper source/drain layer 310B was formed in the upper source/drain trench 300BT.

For example, as illustrated in FIG. 10, the side of the second upper source/drain layer 320B may have a complementary shape to the side of the first upper source/drain layer 310B. For example, the side of the second upper source/drain layer 320B may include a plurality of inclined surfaces corresponding to the first inclined surface 310B_P1 and the second inclined surface 310B_P2 of the first upper source/drain layer 310B. Accordingly, the width along the first direction (X direction) of the second upper source/drain layer 320B may gradually decrease from the upper and lower portions of the upper source/drain trench 300BT toward the center portion. In this case, the fourth width W4 of the center portion of the second upper source/drain layer 320B along the first direction (X direction) may be a minimum width of the second upper source/drain layer 320B along the first direction (X direction). The description of the second upper source/drain layer 320B is substantially the same as the description of the second upper source/drain layer 320B of the implementation of FIGS. 1 to 5, and will therefore be omitted.

Alternatively, as illustrated in FIG. 11, the second upper source/drain layer 320B may be positioned on the first upper source/drain layer 310B. Specifically, the second upper source/drain layer 320B may be conformally positioned on the first inclined surface 310B_P1 and the second inclined surface 310B_P2 of the first upper source/drain layer 310B. That is, the second upper source/drain layer 320B may be positioned on the first inclined surface 310B_P1 and the second inclined surface 310B_P2 of each of the first upper source/drain layer 310B. In this case, the second upper source/drain layer 320B positioned on one side and the second upper source/drain layer 320B positioned on the other side may be spaced apart in the first direction (X direction), but the present disclosure is not limited thereto. For example, the second upper source/drain layer 320B positioned on one side and the second upper source/drain layer 320B positioned on the other side may be connected to each other to form a unit.

In the implementation, the contact structure 180 may be positioned on the upper source/drain pattern 300B. The contact structure 180 may be electrically connected to the upper source/drain pattern 300B through the interlayer insulation layer 190. For example, as illustrated in FIG. 10, the contact structure 180 may be positioned to recess the upper source/drain pattern 300B to a predetermined depth. For example, the contact structure 180 may be recessed within the second upper source/drain layer 320B. In another example, as illustrated in FIG. 11, the contact structure 180 may be positioned on the top surface of the second upper source/drain layer 320B. For example, the contact structure 180 may be positioned on the top surface of the second upper source/drain layer 320B positioned on one side and above the top surface of the second upper source/drain layer 320B positioned on the other side. In this case, even when the second upper source/drain layer 320B positioned on the one side and the second upper source/drain layer 320B positioned on the other side are spaced apart in the first direction (X direction), the second upper source/drain layers 320B positioned on the one side and the other side may be electrically connected by the contact structure 180.

The contact structure 180 may have an inclined side such that the width of the lower portion is narrower than the width of the upper portion, depending on the aspect ratio, but the present disclosure is not limited thereto. The contact structure 180 according to the implementation may include a contact electrode 186, a first barrier layer 184 surrounding the contact electrode 186, and a first silicide film 182 positioned between the first barrier layer 184 and the upper source/drain pattern 300B. The description of the contact structure 180 according to the implementation is substantially the same as the description of the contact structure 180 of the implementation of FIGS. 1 to 5, and will therefore be omitted.

FIG. 12 is a cross-sectional view corresponding to region A1 of FIG. 2 of semiconductor devices.

The implementations illustrated in FIG. 12 is substantially identical to the implementation illustrated in FIG. 11, and therefore will not be described but in terms of differences

The present implementation differs from the previous implementations in that dummy source/drain patterns 400B are included, which will be described below.

A semiconductor device 100 includes a substrate 101, an active pattern 105 positioned on the substrate 101, a plurality of channel patterns 140 positioned on the active pattern 105, a middle dielectric isolation structure MDI positioned between a plurality of lower channel patterns 140A and a plurality of upper channel patterns 140B, and a field insulation layer 110 positioned on the substrate 101, a gate structure 160 positioned on the active pattern 105, a lower source/drain pattern 300A and a dummy source/drain pattern 400B positioned on at least one side of the gate structure 160, and a barrier structure 170 positioned between the lower source/drain pattern 300A and the dummy source/drain pattern 400B.

Further, in the semiconductor device 100 according to the implementation, the dummy source/drain patterns 400B may include first dummy source/drain patterns 410B and second dummy source/drain patterns 420B.

The dummy source/drain patterns 400B may be positioned on the lower source/drain patterns 300A. The dummy source/drain patterns 400B may be spaced apart from the lower source/drain patterns 300A in a third direction (Z direction). For example, the barrier structure 170 may be positioned between the dummy source/drain patterns 400B and the lower source/drain pattern 300A, and the dummy source/drain patterns 400B and the lower source/drain pattern 300A may be spaced apart by the barrier structure 170. Accordingly, the dummy source/drain patterns 400B and the lower source/drain pattern 300A may be electrically insulated.

The dummy source/drain patterns 400B may be positioned on at least one side of the upper gate structure 160B. For example, the dummy source/drain patterns 400B may be positioned on opposite sides of the upper gate structure 160B. The dummy source/drain patterns 400B may be connected with the plurality of upper channel patterns 140B.

The dummy source/drain patterns 400B may be positioned within the dummy source/drain trench 400BT. For example, the dummy source/drain patterns 400B may be positioned on one side and the other side of the dummy source/drain trench 400BT, respectively. The bottom surface of the dummy source/drain trench 400BT may be defined by the barrier structure 170 but is not limited thereto. A sidewall 400BT_S of the dummy source/drain trench 400BT may be defined by the plurality of upper channel patterns 140B and the plurality of lower gate structures 160A.

In the implementation, the dummy source/drain patterns 400B may be spaced apart in the first direction (X direction). For example, the dummy source/drain patterns 400B positioned on one side of the dummy source/drain trench 400BT and the dummy source/drain patterns 400B positioned on the other side of the dummy source/drain trench 400BT may be spaced apart in the first direction (X direction).

The dummy source/drain patterns 400B may include first dummy source/drain patterns 410B and second dummy source/drain patterns 420B.

The sides of the first dummy source/drain patterns 410B may include a plurality of inclined surfaces that are inclined at a predetermined angle from the top surface of the substrate 101. For example, the first dummy source/drain patterns 410B may include a first inclined surface 410B_P1 that narrows in width along the first direction (X direction) as it goes away from the top surface of the substrate 101 and a second inclined surface 410B_P2 that widens in width along the first direction (X direction) as it goes away from the top surface of the substrate 101. The first inclined surface 410B_P1 and the second inclined surface 410B_P2 of the first dummy source/drain pattern 410B may have different inclinations. Accordingly, the width of the first dummy source/drain patterns 410B along the first direction (X direction) may gradually increase from the upper and lower portions of the dummy source/drain trench 400BT toward the center portion. The side of the first dummy source/drain pattern 410B may have a convex shape from the sidewall 300BT_S of the upper source/drain trench 300BT.

According to the implementation, the second dummy source/drain patterns 420B may be positioned on the first dummy source/drain patterns 410B. Specifically, the second dummy source/drain patterns 420B may be conformally positioned on the first inclined surface 410B_P1 and the second inclined surface 410B_P2 of the first dummy source/drain patterns 410B. That is, the second dummy source/drain patterns 420B may be positioned on the first inclined surface 410B_P1 and the second inclined surface 410B_P2 of the respective first dummy source/drain patterns 410B. In this case, the second dummy source/drain pattern 420B positioned on one side and the second dummy source/drain pattern 420B positioned on the other side may be spaced apart in the first direction (X direction).

The contact structure 180 according to the implementation may be electrically connected to the lower source/drain pattern 300A while through the interlayer insulation layer 190 and the barrier structure 170. The contact structure 180 may be positioned on the top surface of the second lower source/drain layer 320A. For example, the contact structure 180 may be positioned to recess the lower source/drain pattern 300A to a predetermined depth. For example, the contact structure 180 may be recessed within the second lower source/drain layer 320A.

In the implementation, the contact structure 180 may extend in the third direction (Z direction) between the dummy source/drain patterns 400B. The interlayer insulation layer 190 may be positioned between the contact structures 180 and the dummy source/drain patterns 400B. Thus, the contact structure 180 and the dummy source/drain patterns 400B may be in non-contact with each other, and the contact structure 180 and the dummy source/drain patterns 400B may be electrically insulated from each other.

The contact structure 180 may have an inclined side such that the width of the lower portion is narrower than the width of the upper portion, depending on the aspect ratio, but is not limited thereto. The contact structure 180 according to the implementation may include a contact electrode 186, a first barrier layer 184 surrounding the contact electrode 186, and a first silicide film 182 positioned between the first barrier layer 184 and the lower source/drain pattern 300A. A description of the contact structure 180 according to the implementation is substantially the same as the description of the contact structure 180 of the implementation of FIG. 11, and will therefore be omitted.

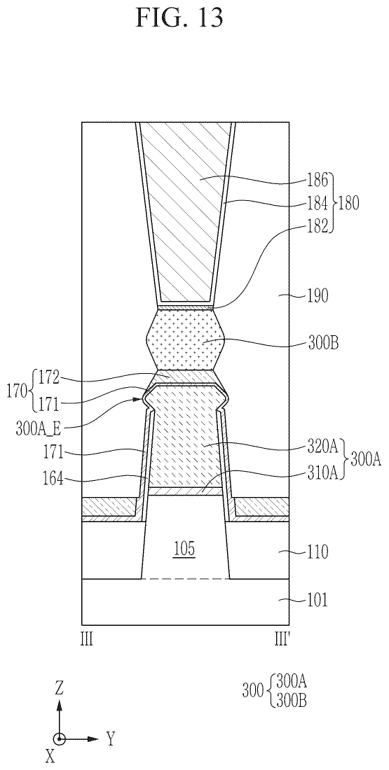

Hereinafter, a semiconductor device will be described with further reference to FIGS. 13 to 20.

FIG. 13 is a cross-sectional view corresponding to a region taken along III-III′ of FIG. 1 of the semiconductor devices.

The implementation illustrated in FIG. 13 is substantially identical to the implementation illustrated in FIGS. 1 to 5, and therefore will not be described but in terms of differences

In the present implementation, the shape of the lower source/drain pattern 300A differs from the previous implementation and will be described below.

The lower source/drain pattern 300A of the semiconductor device 100 according to the implementation may include a portion positioned between the gate spacers 164 and a protrusion 300A_E positioned on the gate spacers 164.

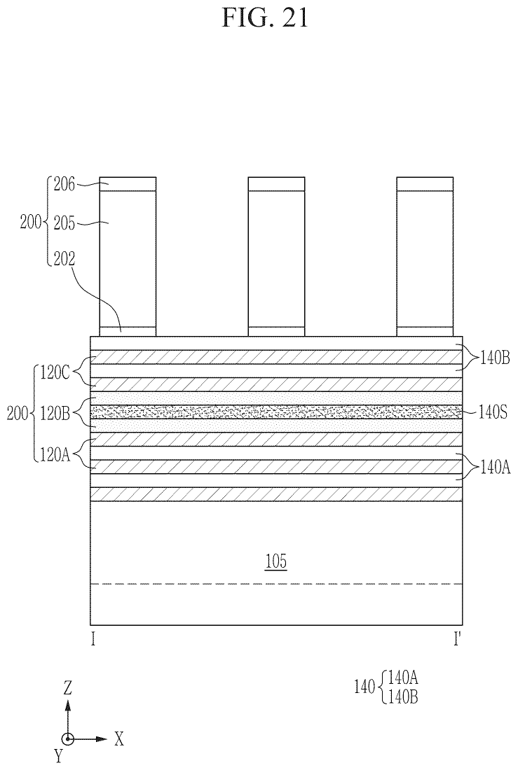

The protrusions 300A_E may be positioned on top of the lower source/drain pattern 300A. The protrusion 300A_E may protrude along the second direction (Y direction) from the center portion of the lower source/drain pattern 300A. That is, the protrusions 300A_E may protrude from the center portion of the lower source/drain pattern 300A toward the interlayer insulation layer 190. This may be due to a process characteristic in which in the process of forming the lower source/drain trench 300AT by etching at least a portion of a lower sacrificial layer 120A (in FIG. 21), the plurality of lower channel patterns 140A, and the first barrier pattern 171, exposed portions of a top of the first barrier pattern 171 and a top of the gate spacer 164 are removed together.

In the implementation, the gate spacer 164 may cover a portion of the side of the lower source/drain pattern 300A. For example, the gate spacer 164 may cover a portion of the side of the lower source/drain pattern 300A, and may not cover the side of the protrusion 300A_E.

In the implementation, the first barrier pattern 171 may be positioned on a side of the gate spacer 164, on a side of the protrusion 300A_E, and on a top surface of the lower source/drain pattern 300A. That is, the first barrier pattern 171 may cover the side of the protrusion 300A_E. The first barrier pattern 171 may be positioned between the protrusion 300A_E and the interlayer insulation layer 190.

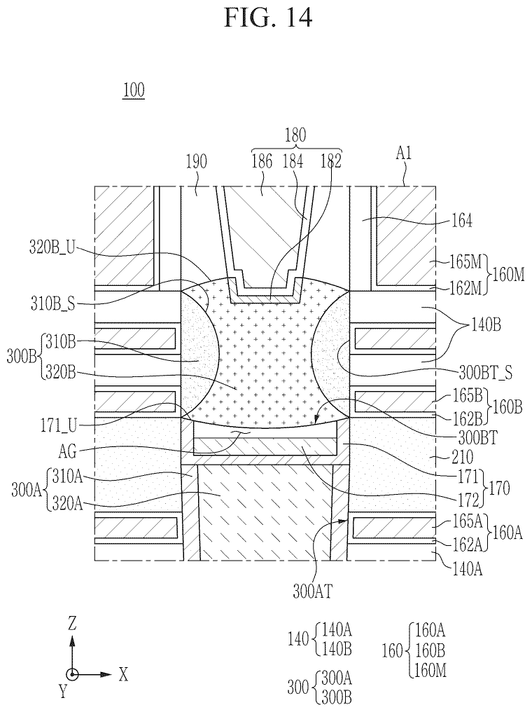

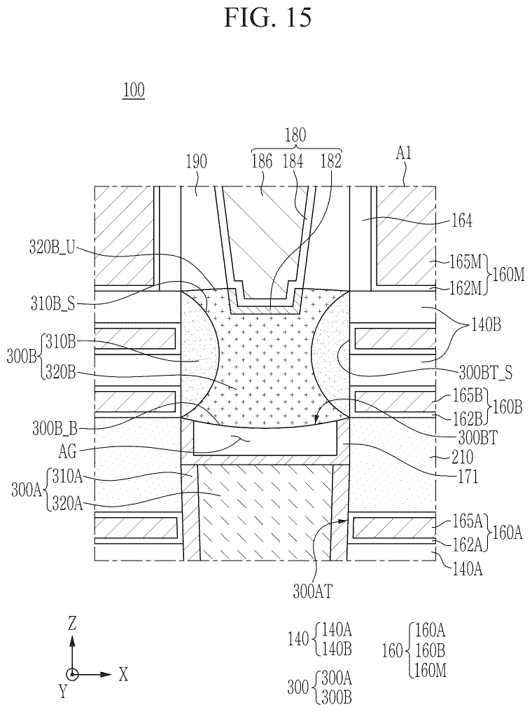

FIGS. 14 and 15 are cross-sectional views corresponding to region A1 of FIG. 2 of the semiconductor devices.

The implementations illustrated in FIGS. 14 and 15 are substantially identical to the implementation illustrated in FIGS. 1 to 5, and therefore will not be described but in terms of differences

The present implementation differs from the previous implementations in that an air gap AG is included below the upper source/drain pattern 300B, which will be described below.

The semiconductor device 100 according to the implementation may further include an air gap AG between the barrier structure 170 and the upper source/drain pattern 300B.

For example, as illustrated in FIG. 14, the air gap AG may be positioned between the second barrier pattern 172 and the second upper source/drain layer 320B. The air gap AG may be defined by an inner wall of the first barrier pattern 171, a top surface of the second barrier pattern 172, and a bottom surface of the second upper source/drain layer 320B. In this case, the top surface of the second barrier pattern 172 may be positioned at a lower level than a top surface 171_U of the first barrier pattern 171. That is, the top surface of the second barrier pattern 172 may be positioned closer to the top surface of the substrate 101 than the top surface 171_U of the first barrier pattern 171. Here, the top surface 171_U of the first barrier pattern 171 may refer to the top surface of a portion of the first barrier pattern 171 positioned between the middle dielectric isolation structure MDI and the second barrier pattern 172.

Alternatively, as illustrated in FIG. 15, the air gap AG may be positioned between the first barrier pattern 171 and the second upper source/drain layer 320B. In this case, the barrier structure 170 may not include the second barrier pattern 172. That is, the air gap AG may be defined by the bottom surface and the inner wall of the first barrier pattern 171 and the bottom surface of the second upper source/drain layer 320B.

In the implementation, the air gap AG may include gas including air or a material used in the manufacturing process of the semiconductor device 100. In the implementation, the air gap AG may be formed by removing a portion or all of the second barrier pattern 172, in the process of forming the first barrier pattern 171 and the second barrier pattern 172 on the lower source/drain pattern 300A, and then removing at least a portion of the first barrier pattern 171 and the second barrier pattern 172 to form the barrier structure 170.

In the implementation, when the air gap AG is positioned on the barrier structure 170, the bottom surface of the second upper source/drain layer 320B may have a convex shape toward the substrate 101. For example, the bottom surface of the second upper source/drain layer 320B may have a rounded shape toward the substrate 101. This is because in the process of forming the second upper source/drain layer 320B by using an epitaxial growth process utilizing the plurality of upper channel patterns 140B as seeds, the second upper source/drain layer 320B may be formed within a portion of the space of the air gap AG.

FIGS. 16 and 17 are cross-sectional views corresponding to a region taken along I-I′ of FIG. 1 of the semiconductor devices

The implementations illustrated in FIGS. 16 and 17 are substantially identical to the implementation illustrated in FIGS. 1 to 5, and therefore will not be described but will be described in terms of differences

The present implementation differs from the previous implementation in that an inner gate spacer 168 is further included, which will be described below.

The semiconductor device 100 according to the implementation may further include an inner gate spacer 168 positioned between the gate structure 160 and the source/drain patterns 300.

The inner gate spacer 168 may be positioned on the side of the gate structure 160. The inner gate spacer 168 may be positioned between the gate structure 160 and the source/drain patterns 300. For example, as illustrated in FIG. 16, the inner gate spacer 168 may be positioned between the lower gate structure 160A and the lower source/drain pattern 300A, and may not positioned between the upper gate structure 160B and the upper source/drain pattern 300B. Alternatively, as illustrated in FIG. 17, the inner gate spacer 168 may be positioned between the lower gate structure 160A and the lower source/drain pattern 300A and between the upper gate structure 160B and the upper source/drain pattern 300B. The inner gate spacer 168 may not be positioned on the side of the main gate structure 160M.

The inner gate spacer 168 may be positioned side by side with the gate structure 160 between the plurality of channel patterns 140 that are adjacent in the third direction (Z direction). The inner gate spacer 168 may be in contact with the gate insulation films 162A and 162B. The gate structure 160 is spaced from the source/drain patterns 300 by the inner gate spacer 168, to be electrically isolated. The side facing the gate structure 160 of the inner gate spacer 168 may have a convexly rounded shape toward the gate structure 160 but is not limited to. The inner gate spacer 168 may include a silicon oxide, a silicon nitride, a silicon nitroxide, a low dielectric constant film, or a combination thereof.

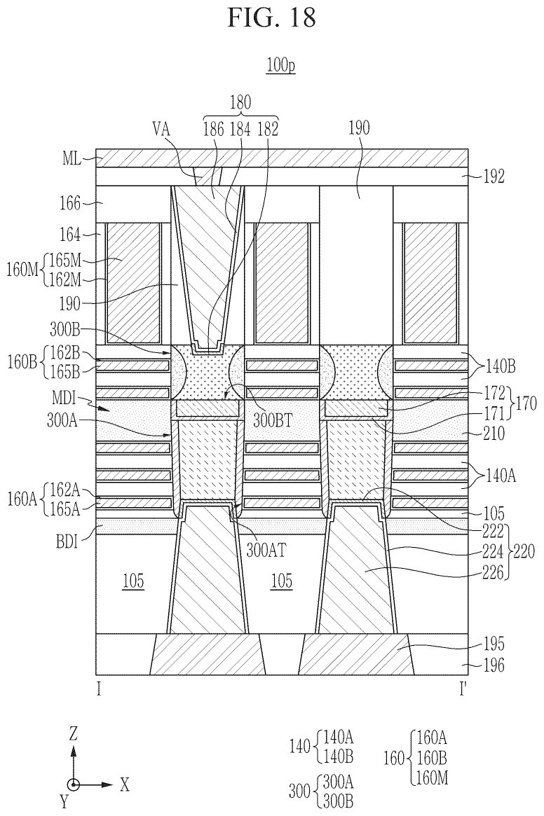

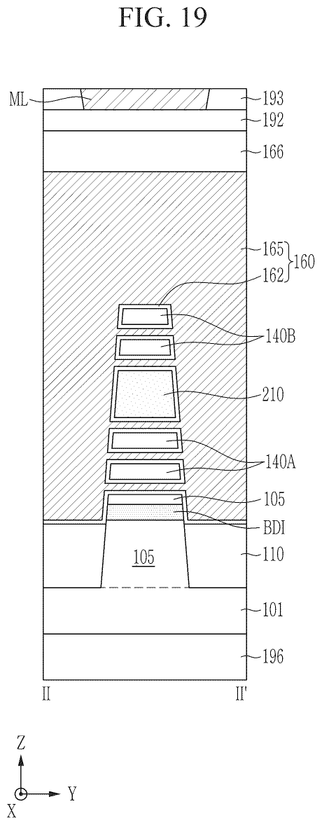

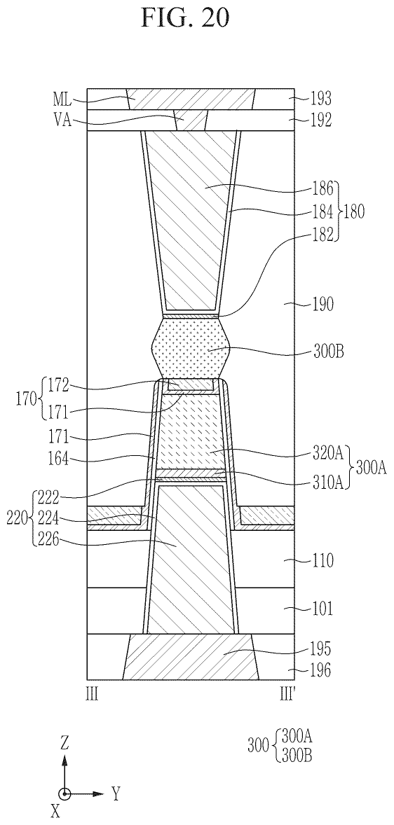

FIG. 18 is a cross-sectional view corresponding to a region taken along I-I′ of FIG. 1 of the semiconductor devices. FIG. 19 is a cross-sectional view corresponding to a region taken along II-II′ of FIG. 1 of the semiconductor devices. FIG. 20 is a cross-sectional view corresponding to a region taken along III-III′ of FIG. 1 of the semiconductor device.

The implementations illustrated in FIGS. 18 to 20 are substantially identical to the implementation illustrated in FIGS. 1 to 5, and therefore will not be described but in terms of differences

The present implementation differs from the previous implementations in that a through via structure 220 is further included, which will be described below.

A semiconductor device 100P may further include an upper insulation layer 192 positioned on the contact structure 180, an upper wiring structure positioned on the upper insulation layer 192, a lower wiring structure positioned below the substrate 101, and a through via structure 220 positioned between the source/drain patterns 300 and the lower wiring structure.

The upper insulation layer 192 may be positioned on the top surface of the capping layer 166, the top surface of the interlayer insulation layer 190, and the top surface of the contact structure 180. The upper insulation layer 192 may include the same material as the interlayer insulation layer 190. The upper insulation layer 192 may include at least one of, for example, silicon oxide (SiO₂), silicon nitride (SiN), silicon nitroxide (SiON), and a low dielectric constant material.

The upper wiring structure may be positioned on the upper insulation layer 192. The top wiring structure may include upper wires ML, an upper via VA, and an upper wiring insulation layer.

The upper wires ML may be positioned on the upper insulation layer 192. The upper wires ML may include metal (for example, copper). The upper wires ML may be electrically connected to the contact structure 180 through the upper via VA. The upper wiring insulation layer may cover the upper wiring structure, and the upper wires ML may be positioned within the upper wiring insulation layer. The upper wiring insulation layer may include at least one of, for example, silicon oxide (SiO₂), silicon nitride (SiN), silicon nitroxide (SiON), and a low dielectric constant film.

The lower wiring structure may be positioned on the bottom surface of the substrate 101. The lower wiring structure may be, for example, a power delivery network that supplies a voltage (for example, a power supply voltage) to the lower source/drain pattern 300A.

The lower wiring structure may include lower wires 195 and a lower wiring insulation layer 196.

The lower wires 195 may be positioned on the bottom surface of the substrate 101. The lower wires 195 may include metal (for example, copper). The lower wires 195 may be electrically connected to the through via structure 220. The lower wiring insulation layer 196 may be positioned on the bottom surface of the substrate 101. The lower wiring insulation layer 196 may cover the lower wiring structure, and the lower wires 195 may be positioned within the lower wiring insulation layer 196. The lower wiring insulation layer 196 may include at least one of, for example, silicon oxide (SiO₂), silicon nitride (SiN), silicon nitroxide (SiON), or low dielectric constant films.

The semiconductor device 100 according to the implementation may further include a bottom dielectric isolation structure BDI positioned between the active patterns 105. The bottom dielectric isolation structure BDI may include substantially the same material as the middle dielectric isolation structure MDI but is not limited thereto.

In FIGS. 18 and 19, the bottom dielectric isolation structure BDI is illustrated as being positioned between the active pattern 105, but is not limited thereto, and the bottom dielectric isolation structure BDI may also be positioned between the active pattern 105 and the lower gate structure 160A. Alternatively, the semiconductor device 100p may not include a bottom dielectric isolation structure BDI. In this case, the substrate 101 may be made of an insulating substrate including an insulating material, and the active pattern 105 may be formed of an insulating pattern including an insulating material.

The through via structure 220 may be positioned between the lower source/drain pattern 300A and the lower wiring structure. The through via structure 220 may be connected with at least one lower source/drain pattern 300A. The through via structure 220 may extend in the third direction (Z direction) from the lower source/drain pattern 300A to the lower wiring structure. The top surface of the through via structure 220 may be connected to the lower source/drain pattern 300A. In the implementation, the lower source/drain pattern 300A and the lower wiring structure may be electrically connected to each other via the through via structure 220. That is, a voltage (for example, a power supply voltage) may be applied from the lower wiring structure to the lower source/drain pattern 300A via the through via structure 220.

The through via structure 220 may include a through via 226, a second barrier layer 224 surrounding the through via 226, and a second silicide film 222 positioned between the second barrier layer 224 and the lower source/drain pattern 300A.

The through via 226 may include at least one of, for example, a metal, a metal alloy, a conductive metal nitride, a conductive metal carbide, a conductive metal oxide, a conductive metal carbonitride, and a two-dimensional (2D) material. The second barrier layer 224 may include, for example, a metal nitride, such as, titanium nitride (TiN), tantalum nitride (TaN), or tungsten nitride (WN).

The second silicide film 222 may surround a portion of the through via 226 that are recessed into the lower source/drain pattern 300A. The second silicide film 222 may include a metal-silicide. For example, the second silicide film 222 may include at least one of titanium-silicide, tantalum-silicide, tungsten-silicide, nickel-silicide, and cobalt-silicide. In implementations, the number and arrangement of the conductive layers configuring the through via structure 220 may be varied. In some implementations, the second barrier layer 224 and/or the second silicide film 222 may be omitted.

Although not illustrated, the through via structure 220 may further include an insulating liner positioned on an outer surface of the through via structure 220 for insulation from the substrate 101.

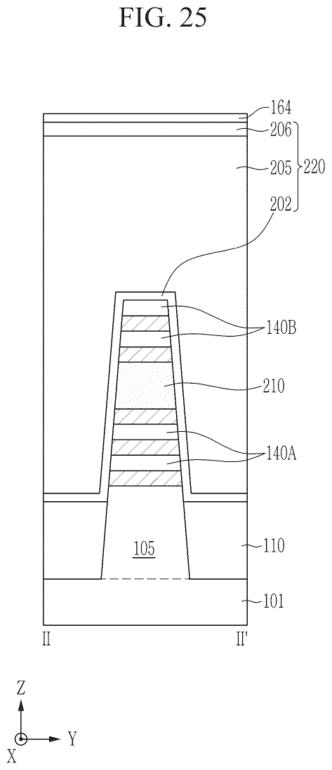

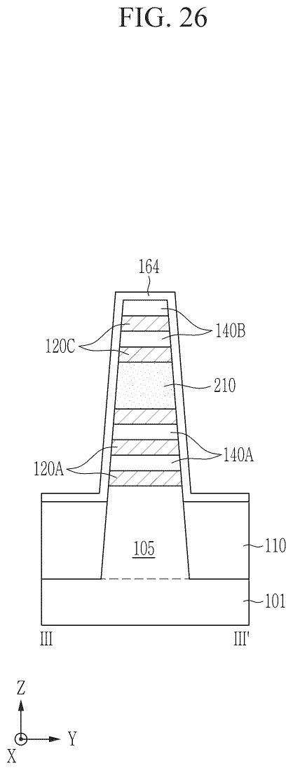

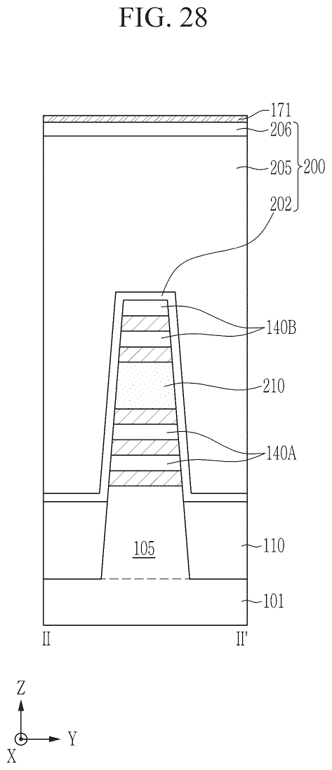

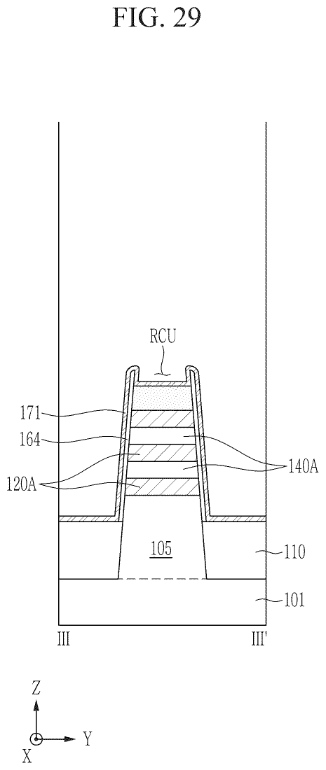

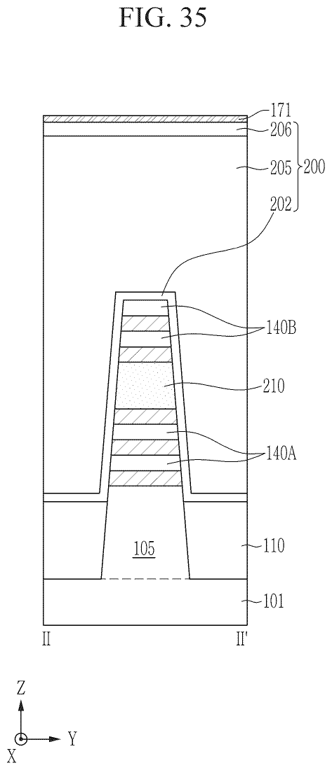

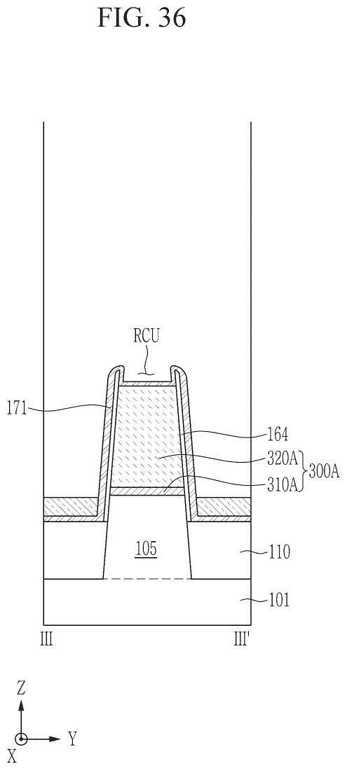

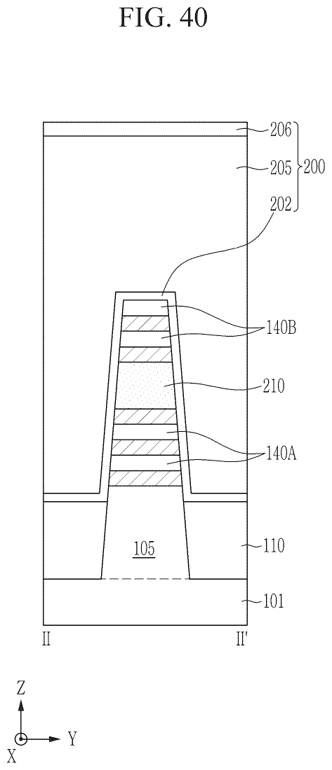

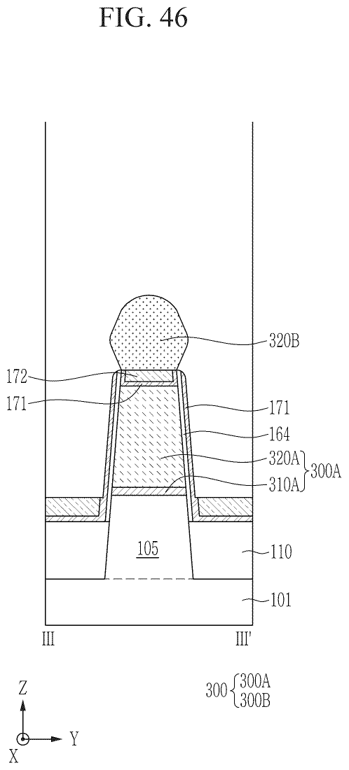

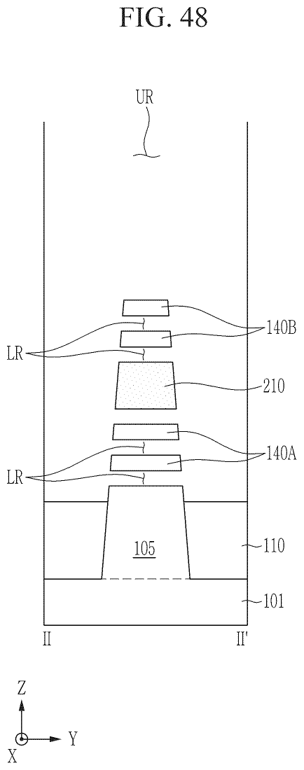

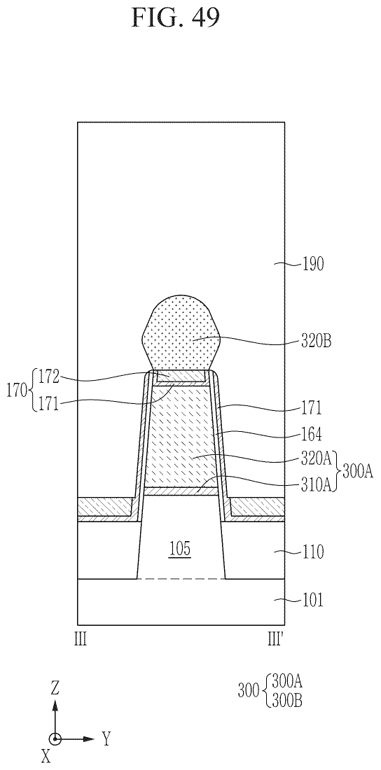

Hereinafter, a method of manufacturing a semiconductor device according to the implementation will be described with reference to FIGS. 21 to 53.

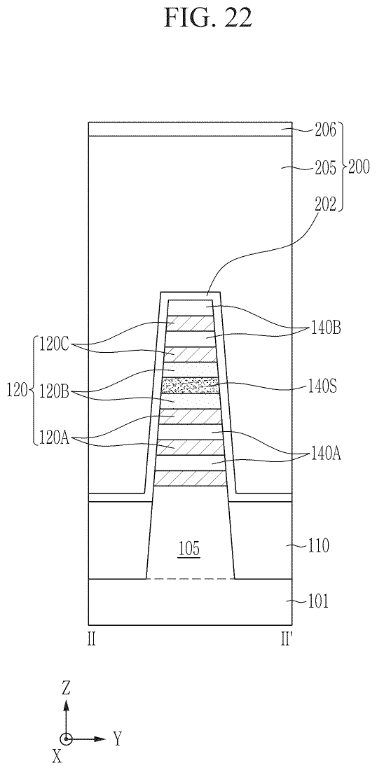

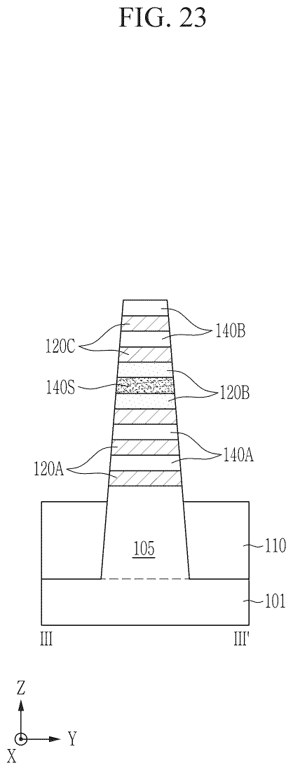

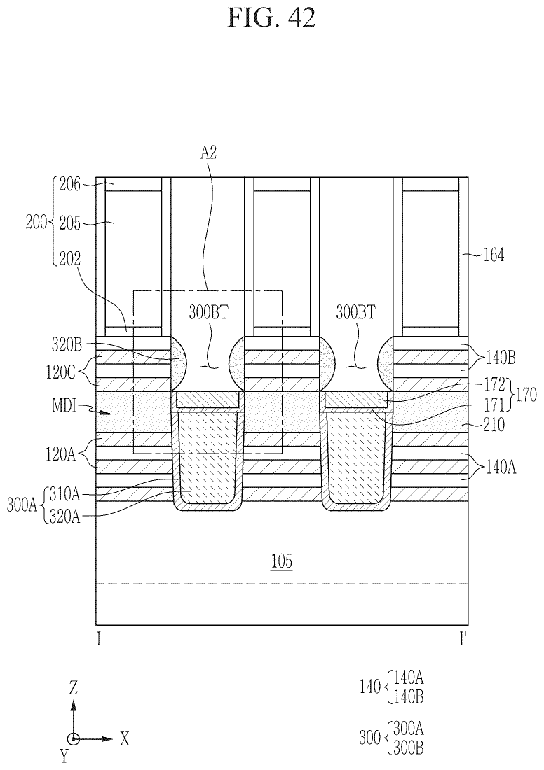

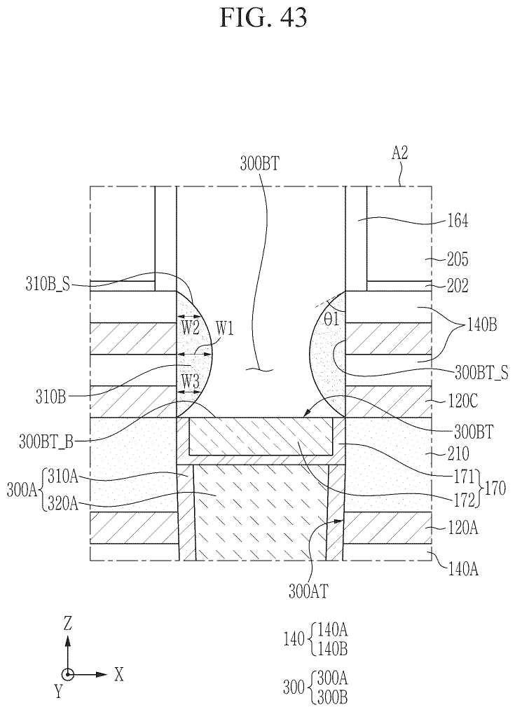

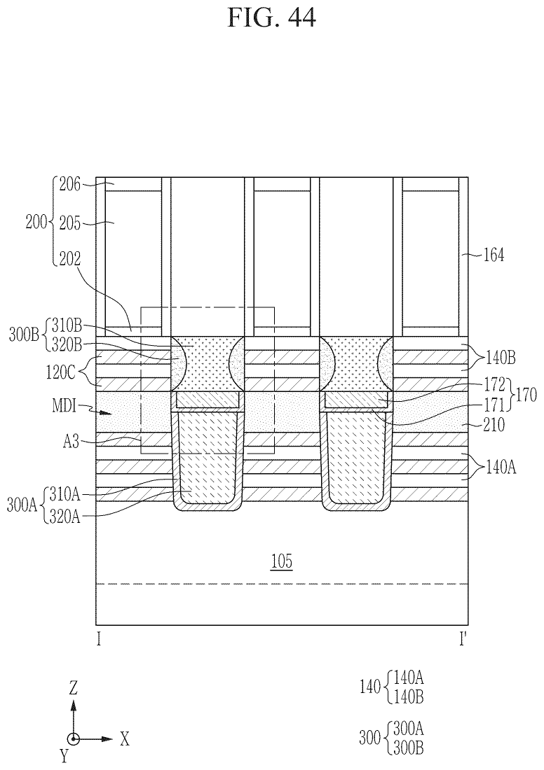

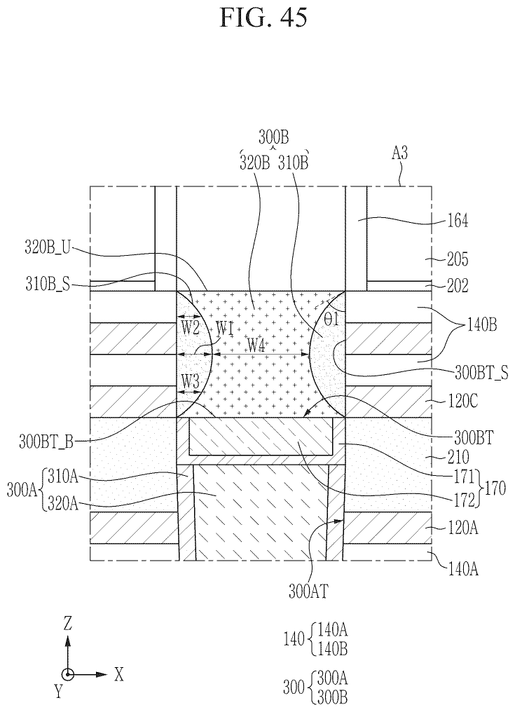

FIGS. 21 to 53 are cross-sectional views illustrating an example method of manufacturing a semiconductor device. In the implementation, FIGS. 21, 24, 27, 30, 32, 34, 37, 39, 42, 44, 47, 50, and 52 are cross-sectional views corresponding to a region taken along I-I′ of FIG. 1, illustrating a method of manufacturing a semiconductor device. FIGS. 22, 25, 28, 35, 40, 48, 51, and 53 are cross-sectional views corresponding to a region taken along II-II′ of FIG. 1, illustrating the method of manufacturing the semiconductor device according to the implementation. FIGS. 23, 26, 29, 31, 33, 36, 38, 41, 46, and 49 are cross-sectional views corresponding to a region taken along III-III′ of FIG. 1, illustrating the method of manufacturing the semiconductor device according to the implementation. FIG. 43 is an enlarged cross-sectional view of region A2 of FIG. 42. FIG. 45 is an enlarged cross-sectional view of region A2 in FIG. 44.

As illustrated in FIGS. 21 to 23, sacrificial layers 120, a plurality of lower channel patterns 140A, a middle semiconductor pattern 140S, and a plurality of upper channel patterns 140B may be formed on a substrate 101, and a sacrificial gate structure 200 may be formed.

First, the sacrificial layers 120, the plurality of lower channel patterns 140A, the middle semiconductor pattern 140S, and the plurality of upper channel patterns 140B are formed on the substrate 101. The substrate 101 may be silicon-on-insulator (SOI) or bulk silicon. Alternatively, the substrate 101 may be a silicon substrate or may include other materials, such as, silicon germanium (SiGe), silicon germanium on insulator (SGOI), indium antimonide, lead telluride compound, indium arsenide, indium phosphide, gallium arsenide, or gallium antimonide but is not limited thereto.

The sacrificial layers 120 may be made of a material having an etch selectivity for the plurality of lower channel patterns 140A, the middle semiconductor patterns 140S, and the plurality of upper channel patterns 140B. The plurality of lower channel patterns 140A, the middle semiconductor patterns 140S, and the plurality of upper channel patterns 140B may include different materials from the sacrificial layers 120. For example, the plurality of lower channel patterns 140A, the middle semiconductor patterns 140S, and the plurality of upper channel patterns 140B may include silicon (Si), and the sacrificial layers 120 may include silicon germanium (SiGe), but the present disclosure are not limited thereto.

The sacrificial layers 120, the plurality of lower channel patterns 140A, and the plurality of upper channel patterns 140B may be formed by performing an epitaxial growth process using the substrate 101 as a seed. The number of the plurality of lower channel patterns 140A, the middle semiconductor patterns 140S, and the plurality of upper channel patterns 140B that are alternately stacked with the sacrificial layers 120 may be varied in implementations.

Next, portions of the sacrificial layers 120, the plurality of lower channel patterns 140A, the middle semiconductor patterns 140S, the plurality of upper channel patterns 140B, and the substrate 101 are removed to form an active structure, and the field insulation layer 110 may be formed.

The active structure may include sacrificial layers 120, the plurality of lower channel patterns 140A, a middle semiconductor pattern 140S, and the plurality of upper channel patterns 140B which are alternately stacked. In addition, the active structure may further include an active pattern 105 formed such that at least a portion of the substrate 101 is removed and protrudes from a top surface of the substrate 101. The active structure may extend in the first direction (X direction). The active structures may be spaced apart in the second direction (Y direction). Accordingly, opposite sides of a middle sacrificial layer 120B and the middle semiconductor pattern 140S may be exposed.

A field insulation layer 110 may be formed on the portion of the substrate 101 from which at least a portion of the substrate has been removed. Accordingly, the active pattern 105 may be positioned on the side of the field insulation layer 110. The process of forming the field insulation layer 110 may include embedding the insulating material and then recessing the insulating material so that the active pattern 105 protrudes. Accordingly, the top surface of the field insulation layer 110 may be positioned at a lower level than the top surface of the active pattern 105, but the present disclosure is not limited to.

Next, a sacrificial gate structure 200 may be formed on the active structure. The sacrificial gate structure 200 may include first and second sacrificial gate electrodes 202 and 205, and a preliminary capping layer 206 positioned sequentially on the plurality of upper channel patterns 140B. The first sacrificial gate electrode 202 may include, for example, silicon oxide (SiO₂), but the present disclosure is not limited thereto. The second sacrificial gate electrode 205 may include, for example, polysilicon, but the present disclosure is not limited thereto. The preliminary capping layer 206 may include, for example, silicon nitride, but the present disclosure is not limited thereto. Accordingly, opposite sides of the middle sacrificial layer 120B and opposite sides of the middle semiconductor pattern 140S portion positioned between the sacrificial gate structures 200 may be exposed.

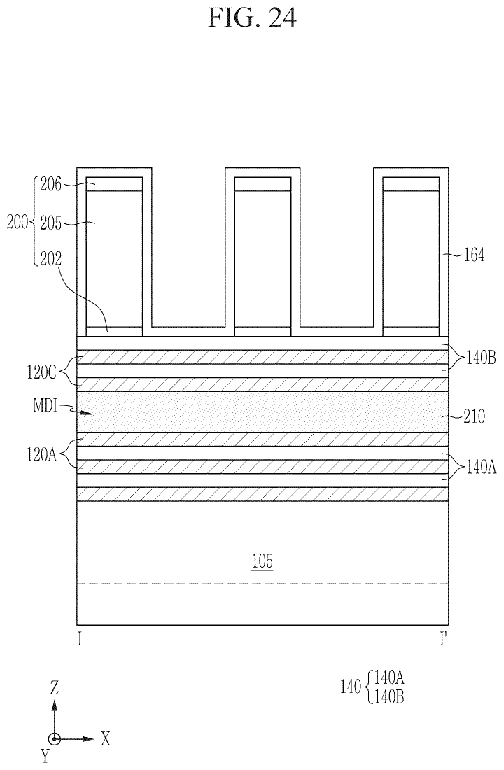

As illustrated in FIGS. 24 to 26, a middle dielectric isolation structure MDI may be formed, and a gate spacer 164 may be formed to cover the top surface and the side of the sacrificial gate structure 200 and the active structure.

First, the middle dielectric isolation structure MDI may be formed by removing the middle sacrificial layer 120B and the middle semiconductor pattern 140S through opposite sides of the exposed middle sacrificial layer 120B and middle semiconductor pattern 140S. The middle sacrificial layer 120B and the middle semiconductor pattern 140S have etch selectivity with respect to the lower sacrificial layer 120A, an upper sacrificial layer 120C, the plurality of lower channel patterns 140A, and plurality of upper channel patterns 140B, and thus may be selectively removed. The middle dielectric isolation structure MDI may be formed by filling the middle insulating pattern 210 in the region where the middle sacrificial layer 120B and the middle semiconductor pattern 140S have been removed. The middle insulating pattern 210 may include, for example, silicon oxide or silicon nitride. However, this method is not limited thereto. For example, the middle semiconductor pattern 140S may not be removed.

Subsequently, the gate spacer 164 may be formed to cover opposite sidewalls and the top surface of the sacrificial gate structure 200. The gate spacer 164 may be formed with a uniform thickness along the top surface and the side of the sacrificial gate structure 200 and active structure. The gate spacer 164 may cover a top surface of the field insulation layer 110.

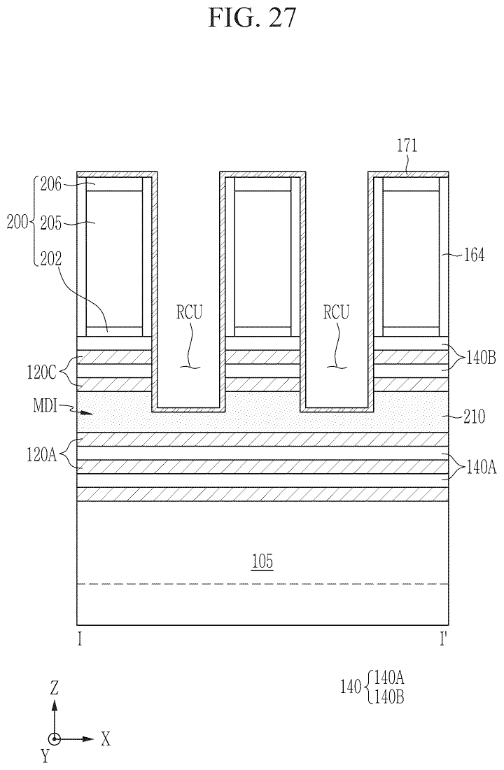

As illustrated in FIGS. 27 to 29, a first barrier pattern 171 may be formed by removing at least a portion of the gate spacer 164, and then removing portions of the plurality of upper channel patterns 140B, the upper sacrificial layer 120C, and the middle dielectric isolation structure MDI.

First, at least a portion of the gate spacer 164 may be removed. The process of removing at least a portion of the gate spacer 164 may be accomplished using a dry etch process. This may result in the removal of the portions of the gate spacer 164 that are positioned on the top surface of the field insulation layer 110, on the top surface of the sacrificial gate structure 200, and on the top surface of the active structure. In this case, the portions of the gate spacer 164 present on the side of the sacrificial gate structure 200 may be removed together, resulting in a reduced thickness.

Then, by using the sacrificial gate structure 200 as a mask, an upper recess region RCU may be formed by removing portions of the exposed upper sacrificial layer 120C, plurality of upper channel patterns 140B, and middle dielectric isolation structure MDI.

The upper recess region RCU may extend through the exposed upper sacrificial layer 120C and plurality of upper channel patterns 140B. The upper recess region RCU may extend through at least a portion of the middle dielectric isolation structure MDI. In the implementation, in the cross-section in the first direction (X direction) and the third direction (Z direction), a lower width and an upper width of the upper recess region RCU may be substantially equal, but the present disclosure is not limited to. For example, the upper recess region RCU may have an inclined side of which a lower width is narrower than an upper width, depending on the aspect ratio. Here, the upper recess region RCU may refer to the region where, in a later process, a barrier structure 170 and the upper source/drain pattern 300B are formed.

Next, the first barrier pattern 171 may be formed to cover the sacrificial gate structure 200, the gate spacer 164, the active structure, and the upper recess region RCU. The first barrier pattern 171 may be formed with a constant thickness along the top surface and the side of the sacrificial gate structure 200, the top surface and the side of the gate spacer 164, the top surface and the side of the active structure, the side and the bottom surface of the upper recess region RCU, and the top surface of the field insulation layer 110. The first barrier pattern 171 may be formed along the top surface and the side of the middle dielectric isolation structure MDI exposed by the upper recess region RCU. The first barrier pattern 171 may include a silicon oxide or silicon nitride or the like.

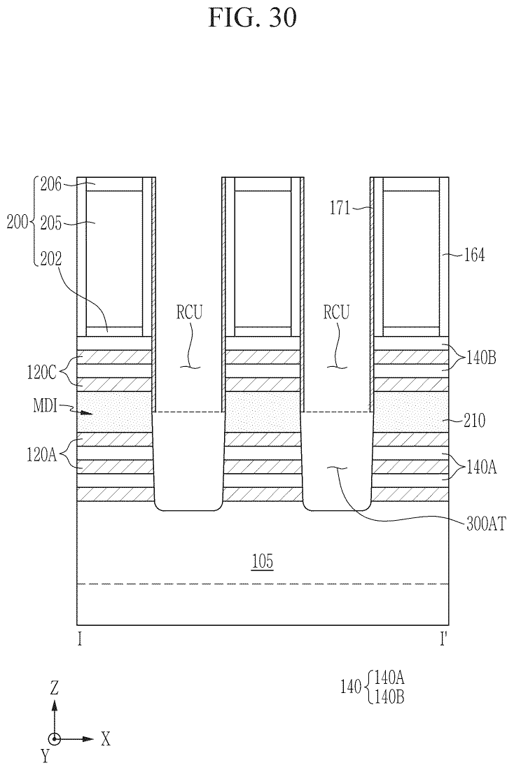

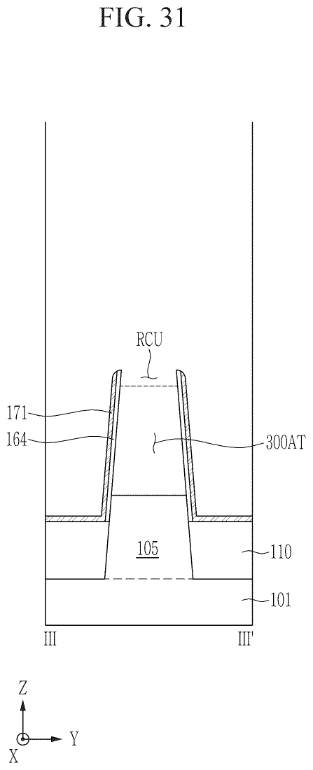

As illustrated in FIGS. 30 and 31, a lower source/drain trench 300AT may be formed by removing a portion of the first barrier pattern 171 and removing portions of the plurality of lower channel patterns 140A, the lower sacrificial layer 120A, and the middle dielectric isolation structure MDI.

First, a portion of the first barrier pattern 171 positioned on the bottom surface of the upper recess region RCU may be etched. The process of removing the first barrier pattern 171 may be performed using a dry etch process but is not limited thereto. Subsequently, the lower source/drain trench 300AT extending in the third direction (Z direction) may be formed by removing a portion of the first barrier pattern 171 and removing at least portions of the exposed middle dielectric isolation structure MDI, of the plurality of lower channel patterns 140A, of the lower sacrificial layer 120A, and of the active pattern 105. The lower source/drain trench 300AT may be formed within the space between the opposing gate spacers 164.

In the implementation, as illustrated in FIG. 31, in the cross-section in the second direction (Y direction) and the third direction (Z direction), the lower source/drain trench 300AT may have a trapezoidal shape that increases in width as it approaches the top surface of the substrate 101. That is, in the cross-section in the second direction (Y direction) and the third direction (Z direction), the lower source/drain trench 300AT may include an inclined surface that is inclined from the top surface of the substrate 101. This may be due to the process characteristic in which the lower source/drain pattern 300A is formed within the space between the gate spacers 164 facing each other

However, the present disclosure is not limited to, and in one example, the width along the second direction (Y direction) of the lower source/drain pattern 300A may be constant.

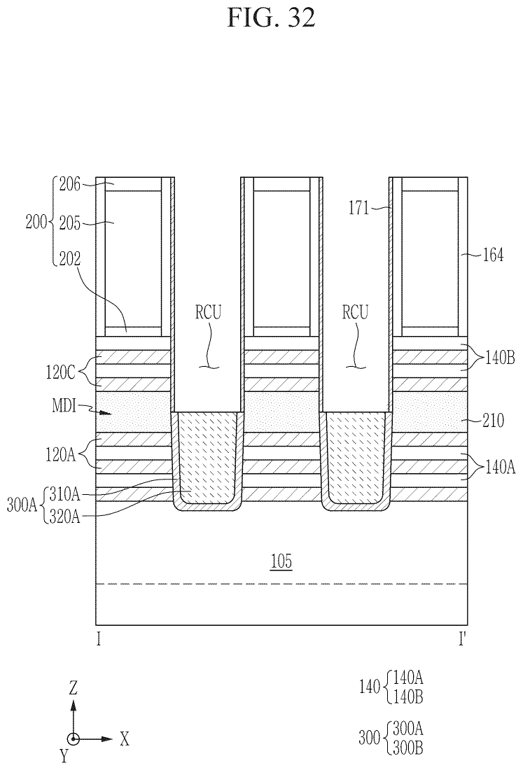

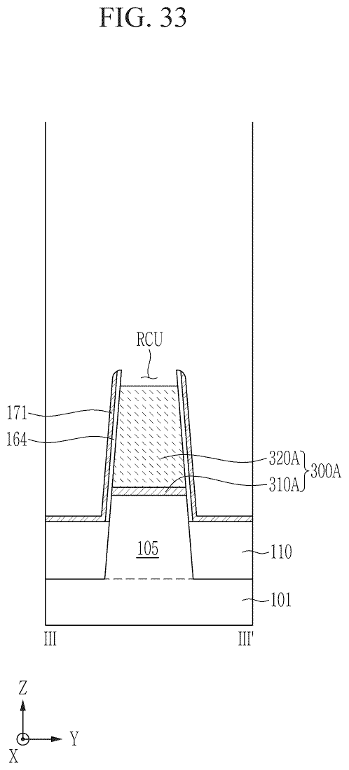

As illustrated in FIGS. 32 and 33, a lower source/drain pattern 300A may be formed within the lower source/drain trench 300AT.

The lower source/drain patterns 300A may be epitaxial patterns formed by a selective epitaxial growth process utilizing the active pattern 105 and the plurality of lower channel patterns 140A as seeds. Specifically, a first lower source/drain layer 310A may be formed along the inner wall and the bottom surface of the lower source/drain trench 300AT, and a second lower source/drain layer 320A may be formed to fill the lower source/drain trench 300AT on the first lower source/drain layer 310A. Accordingly, the lower source/drain pattern 300A may be in contact with the active pattern 105 and the plurality of lower channel patterns 140A.

In the implementation, the top surface of the lower source/drain pattern 300A may be positioned at a higher level than the top surface of the topmost lower sacrificial layer 120A. That is, the top surface of the lower source/drain pattern 300A may be positioned further from the top surface of the substrate 101 than the top surface of the topmost lower sacrificial layer 120A. Accordingly, a portion of the side of the lower source/drain pattern 300A may be in contact with the middle dielectric isolation structure MDI. That is, the top surface of the lower source/drain pattern 300A may be positioned at a higher level than the bottom surface of the middle dielectric isolation structure MDI. However, the present disclosure is not limited thereto, and the top surface of the lower source/drain pattern 300A may be positioned substantially at the same level as the top surface of the topmost lower sacrificial layer 120A.

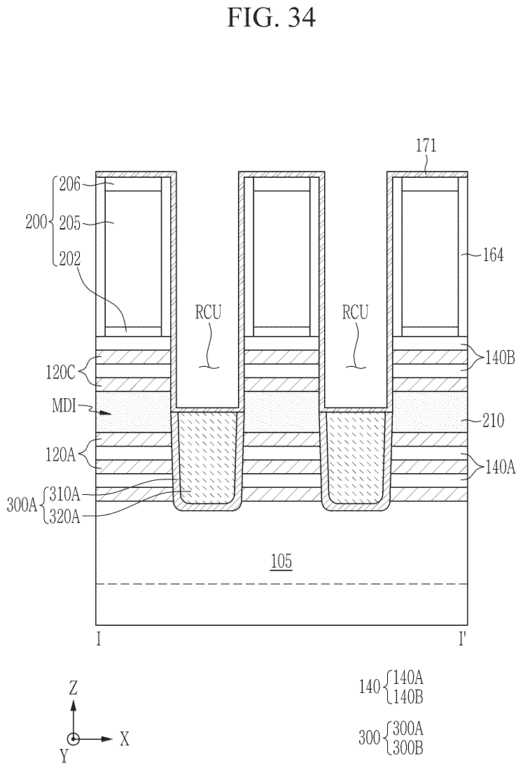

As illustrated in FIGS. 34 to 36, a first barrier pattern 171 may be further formed on the top surface and the side of the sacrificial gate structure 200 and within the upper recess region RCU.

Specifically, a first barrier pattern 171 may be further formed on the top surface of the lower source/drain pattern 300A, the top surfaces of the plurality of upper channel patterns 140B and the upper sacrificial layer 120C exposed by the upper recess region RCU. For example, the first barrier pattern 171 may be further formed by depositing an insulating material along the top surface of the lower source/drain pattern 300A, and the top surfaces of the plurality of upper channel patterns 140B and the upper sacrificial layer 120C. Accordingly, the top surface of the lower source/drain pattern 300A may be covered by the first barrier pattern 171. In this case, the first barrier pattern 171 may be formed together on the side of the gate spacer 164, the top surface of the preliminary capping layer 206, and the top surface of the field insulation layer 110, but the present disclosure is not limited thereto.

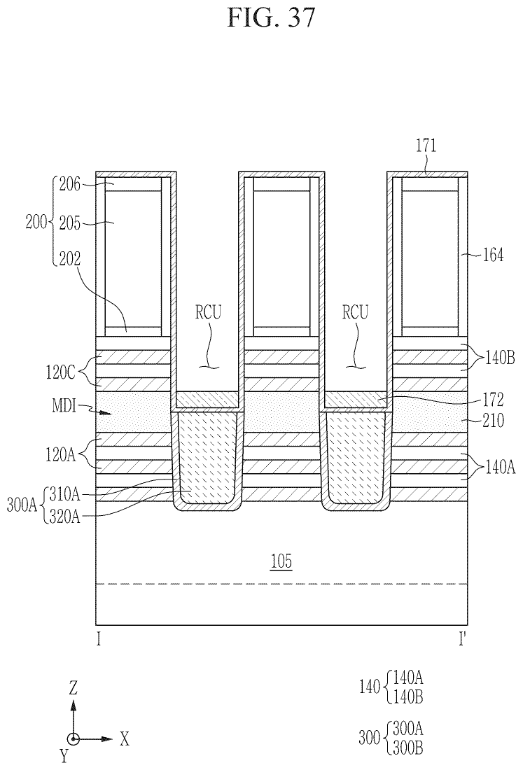

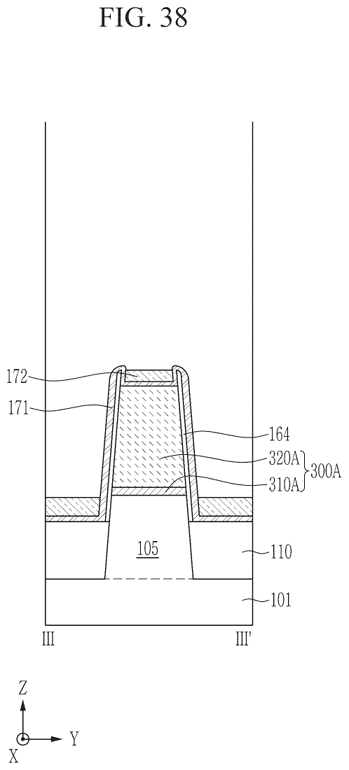

As illustrated in FIGS. 37 and 38, a second barrier pattern 172 may be formed within a portion of the space of the upper recess region RCU.

For example, the second barrier pattern 172 may be formed on the first barrier pattern 171 positioned within the upper recess region RCU. Accordingly, the bottom surface and the side of the second barrier pattern 172 may be surrounded by the first barrier pattern 171. The process of forming the second barrier pattern 172 may be formed by etching at least a portion of the insulating material layer after forming the insulating material layer within the upper recess region RCU. In this case, the second barrier pattern 172 may be formed together with the first barrier pattern 171 positioned on the field insulation layer 110.

In the implementation, the top surface of the second barrier pattern 172 may be substantially the same as the top surface of the middle dielectric isolation structure MDI, but is not limited to. For example, as in the implementation of FIG. 7, the top surface of the second barrier pattern 172 may be positioned at a lower level than the top surface of the middle dielectric isolation structure MDI.

In the implementation, the top surface of the second barrier pattern 172 is illustrated as flat, but is not limited thereto, and for example, the top surface of the second barrier pattern 172 may have a convex shape toward the substrate 101. The shape may be formed by forming an insulating material layer on the first barrier pattern 171 and then removing at least a portion of the insulating material layer. In this case, a space may be provided in which an air gap may be formed, as in the implementation of FIG. 14.

Additionally, it is described in the implementation that the second barrier pattern 172 is formed on the first barrier pattern 171, but the present disclosure is not limited thereto. For example, as in the implementation of FIG. 15, such a shape may be formed by forming an insulating material layer over the first barrier pattern 171 and then removing at least a portion of the insulating material layer, such that the insulating material layer is completely removed.

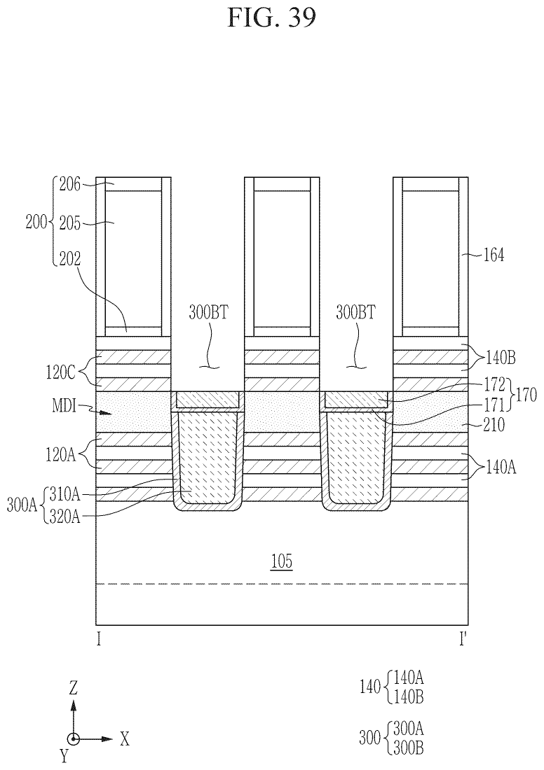

As illustrated in FIGS. 39 to 41, at least a portion of the first barrier pattern 171 may be removed to form the barrier structure 170.

For example, a portion of the exposed first barrier pattern 171 may be removed. That is, the portion of the first barrier pattern 171 that is positioned on the top surface of the preliminary capping layer 206 and the side of the gate spacer 164 may be removed. In this case, the portion of the first barrier pattern 171 positioned on the lower source/drain pattern 300A is not exposed by the second barrier pattern 172 and may not be etched. Accordingly, the barrier structure 170 may be formed that includes the first barrier pattern 171 and the second barrier pattern 172 positioned on the lower source/drain pattern 300A.

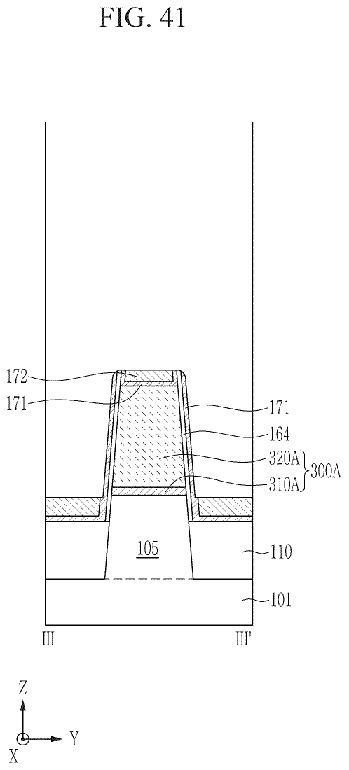

In this case, a portion of the first barrier pattern 171 positioned on the side of the gate spacer 164 may remain. For example, as illustrated in FIG. 41, the first barrier pattern 171 may remain on the side of the gate spacer 164. However, the present disclosure is not limited thereto, and the portion of the first barrier pattern 171 positioned on the side of the gate spacer 164 may be completely removed.

In the implementation, by forming the barrier structure 170 within the upper recess region RCU, an upper source/drain trench 300BT may be formed. The bottom surface of the upper source/drain trench 300BT may be defined by the barrier structure 170. The sidewall of the upper source/drain trench 300BT may be defined by the plurality of upper channel patterns 140B and the upper sacrificial layer 120C.

As illustrated in FIGS. 42 and 43, a first upper source/drain layer 310B may be formed on a sidewall 300BT_S of the upper source/drain trench 300BT.

Specifically, a first upper source/drain layer 310B may be formed on the sidewall 300BT_S of the upper source/drain trench 300BT by using opposite sides of the plurality of upper channel patterns 140B as seeds. Accordingly, the first upper source/drain layer 310B positioned along the sidewall 300BT_S of the upper source/drain trench 300BT may be in contact with the plurality of upper channel patterns 140B.

In the implementation, the first upper source/drain layer 310B may not cover at least a portion of the bottom surface 300BT_B of the upper source/drain trench 300BT. For example, the first upper source/drain layer 310B may not be positioned on the bottom surface 300BT_B of the upper source/drain trench 300BT. This may be due to the process characteristic that the first upper source/drain layer 310B is formed by using opposite sides of the plurality of upper channel patterns 140B as seeds. That is, unlike the lower source/drain pattern 300A, which is the pattern formed using the top surface of the active pattern 105 and opposite sides of the plurality of lower channel patterns 140A as seeds, the upper source/drain pattern 300B may be a pattern formed using only opposite sides of the plurality of upper channel patterns 140B as seeds. Accordingly, the first upper source/drain layer 310B may not cover at least a portion of the bottom surface 300BT_B of the upper source/drain trench 300BT.

In the implementation, the first upper source/drain layer 310B may be in contact with the plurality of upper channel patterns 140B and the upper gate structures 160B. The first upper source/drain layers 310B may overlap the plurality of upper channel patterns 140B and the upper gate structure 160B in the first direction (X direction). In one example, an edge of the first upper source/drain layer 310B may be aligned with a top surface of the topmost upper channel pattern 140B. Additionally, the first upper source/drain layers 310B may not overlap the middle dielectric isolation structure MDI and the gate spacer 164 in the second direction (Y direction). However, the present disclosure is not limited thereto, and an additional inner gate spacer 168 may be positioned between the first upper source/drain layer 310B and the upper gate structure 160B, as illustrated in the implementation of FIG. 17.

In the implementation, the side 310B_S of the first upper source/drain layers 310B may have a convex shape from the sidewall 300BT_S of the upper source/drain trench 300BT. In one example, the side 310B_S of the first upper source/drain layer 310B may include a rounded curved surface convex from the sidewall 300BT_S of the upper source/drain trench 300BT.

Accordingly, the width of the first upper source/drain layer 310B along the first direction (X direction) may gradually increase from the upper and lower portions of the first upper source/drain layers 310B toward the center portion. For example, a first width W1 of the center portion of the first upper source/drain layer 310B along the first direction (X direction) may be greater than a second width W2 of a top portion of the first upper source/drain layer 310B along the first direction (X direction). Further, the first width W1 of the center portion of the first upper source/drain layer 310B along the first direction (X direction) may be greater than the third width W3 of the lower portion of the first upper source/drain layer 310B along the first direction (X direction). In this case, the first width W1 of the center portion of the first upper source/drain layer 310B along the first direction (X direction) may be a maximum width of the first upper source/drain layer 310B along the first direction (X direction). In one example, the first width W1 of the center portion of the first upper source/drain layer 310B along the first direction (X direction) may be equal to or greater than about 0 nm and less than about 10 nm.

Additionally, a first angle θ1 formed by the side 310B_S of the first upper source/drain layer 310B and the sidewall 300BT_S of the upper source/drain trench 300BT may be from 0° to 90°. In one example, a first angle θ1 formed by the side 310B_S of the first upper source/drain layer 310B and the sidewall 300BT_S of the upper source/drain trench 300BT may be 80° to 90°. In this range, when a second upper source/drain layer 320B is formed between the first upper source/drain layers 310B, the second upper source/drain layer 320B may be formed to completely fill the upper source/drain trench 300BT.

In the implementation, the side 310B_S of the first upper source/drain layer 310B is illustrated to be curved, but the present disclosure is not limited thereto, and the side 310B_S of the first upper source/drain layer 310B may be varied within the range to have a convex shape from the sidewall 300BT_S of the upper source/drain trench 300BT. For example, as illustrated in the implementation of FIG. 6, the side 310B_S of the first upper source/drain layer 310B may further include a side extending in the third direction (Z direction). Alternatively, as in the implementation of FIGS. 10 and 11, the side 310B_S of the first upper source/drain layer 310B may include a plurality of inclined surfaces.

The first upper source/drain layer 310B may include a semiconductor material. For example, the first upper source/drain layer 310B may include a semiconductor material, such as silicon (Si) or silicon germanium (SiGe).

In the implementation, the first upper source/drain layers 310B may contain impurities. For example, when the second transistor structure is p-type, the first upper source/drain layer 310B may include p-type impurities. In one example, the first upper source/drain layer 310B may include B, V, In, Ga, Al, or a combination thereof.

As illustrated in FIGS. 44 to 46, a second upper source/drain layer 320B may be formed between the first upper source/drain layers 310B.

Specifically, the second upper source/drain layer 320B may fill the portion left after the first upper source/drain layer 310B is formed in the upper source/drain trench 300BT. For example, the second upper source/drain layer 320B may be formed on the barrier structure 170 that defines the bottom surface 300BT_B of the upper source/drain trench 300BT. Accordingly, the side of the second upper source/drain layer 320B may be formed to have a complementary shape to the side of the first upper source/drain layer 310B. For example, the side 310B_S of the first upper source/drain layer 310B may be formed to have a convex shape from the sidewall 300BT_S of the upper source/drain trench 300BT, and the side of the second upper source/drain layer 320B may be formed to have a convex shape toward the center portion of the second upper source/drain layer 320B.

In the implementation, a top surface 320B_U of the second upper source/drain layer 320B may be positioned at the same level as the top surface of the topmost upper channel pattern 140B among the plurality of upper channel patterns 140B. Additionally, the top surface 320B_U of the second upper source/drain layer 320B may include a flat portion. However, the present disclosure is not limited thereto, and the top surface 320B_U of the second upper source/drain layer 320B may be positioned at a higher level than the top surface of the topmost upper channel pattern 140B among the plurality of upper channel pattern 140B, as illustrated in the implementation of FIG. 7. Additionally, as in the implementation of FIGS. 8 and 9, a bottom surface of the second upper source/drain layer 320B may have a convex shape toward the substrate 101.

The second upper source/drain layer 320B may include a semiconductor material. For example, the second upper source/drain layer 320B may include the same material as the first upper source/drain layer 310B. In one example, the first upper source/drain layer 310B and the second upper source/drain layer 320B may include the semiconductor material silicon (Si) or silicon germanium (SiGe).

In this case, the concentrations of the constituent materials of the first upper source/drain layer 310B and the second upper source/drain layer 320B may be different. For example, when the first upper source/drain layers 310B and the second upper source/drain layer 320B include silicon germanium (SiGe), the concentration of germanium (Ge) in the second upper source/drain layer 320B may be greater than the concentration of germanium (Ge) in the first upper source/drain layer 310B. In one example, the germanium (Ge) concentration in the second upper source/drain layer 320B may be equal to or greater than 60 at % and less than 70 at %, but the present disclosure is not limited thereto. In this range, when the second upper source/drain layer 320B is formed between the first upper source/drain layers 310B, the second upper source/drain layer 320B may include portions of the top surface 320B_U and the bottom surface that are flat. However, the present disclosure is not limited thereto, as in the implementation of FIGS. 8 and 9, the germanium (Ge) concentration of the second upper source/drain layer 320B may be less than 60 at %.

In the implementation, the first upper source/drain layers 310B and/or the second upper source/drain layers 320B may be doped with impurities. For example, when the first transistor structure is p-type, the first upper source/drain layers 310B and/or the second upper source/drain layers 320B may include p-type impurities. In one example, the first upper source/drain layer 310B and the second upper source/drain layer 320B may include B, C, In, Ga, Al, or a combination thereof. In this case, the material of the impurity contained in the first upper source/drain layer 310B may be different from the material of the impurity contained in the second upper source/drain layer 320B. Alternatively, the concentration of the impurity doped in the first upper source/drain layer 310B may be different from the concentration of the impurity doped in the second upper source/drain layer 320B. In this case, the concentration of p-type impurities doped in the second upper source/drain layer 320B may be less than the concentration of p-type impurities doped in the first upper source/drain layer 310B, but the present disclosure is not limited thereto.

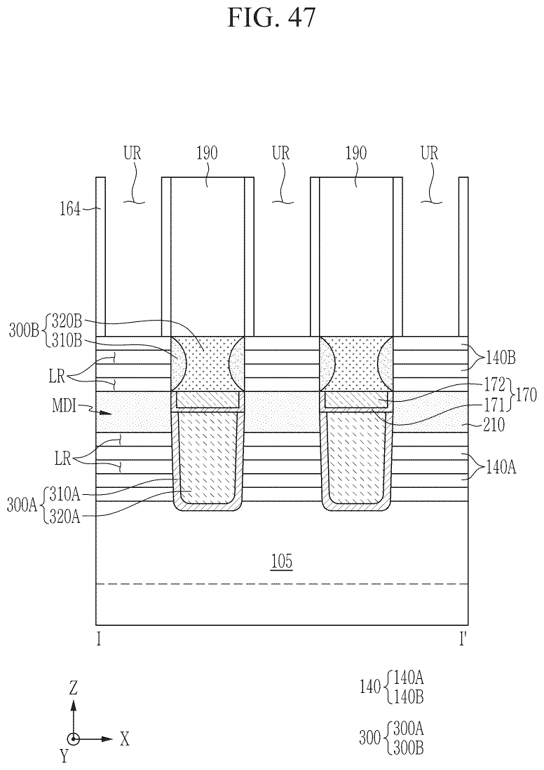

As illustrated in FIGS. 47 to 49, first, an interlayer insulation layer 190 may be formed on the upper source/drain pattern 300B. Subsequently, a lower gate trenchLR may be formed between the plurality of channel patterns 140 by removing the sacrificial gate structure 200, and removing the upper sacrificial layer 120C and the lower sacrificial layer 120A and an upper gate trench between the gate spacers 164 and on the uppermost upper channel 140B. In some implementations, the process of removing the sacrificial gate structure 200, the upper sacrificial layer 120C, and the lower sacrificial layer 120A may occur simultaneously.

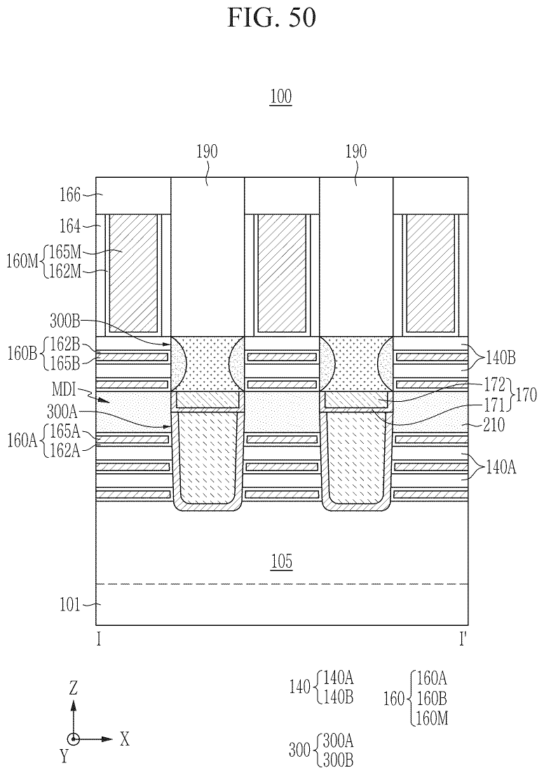

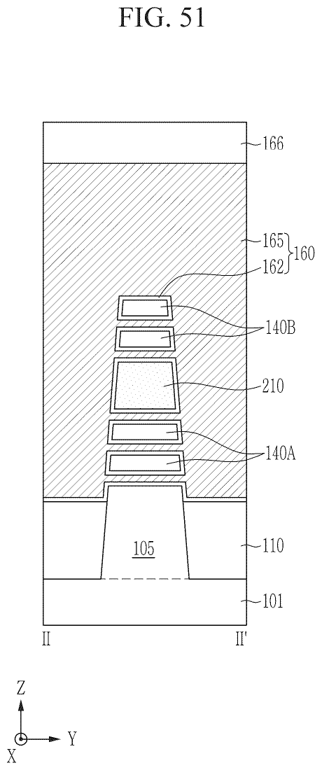

As illustrated in FIGS. 50 and 51, sub-gate insulation films 162A and 162B may be formed within the lower gate trench LR and a main gate insulation film 162M may be formed within the upper gate trench UR, sub-gate electrodes 165A and 165B and a main gate electrode 165M may be formed, and a capping layer 166 may be formed on a main gate electrode 165M.

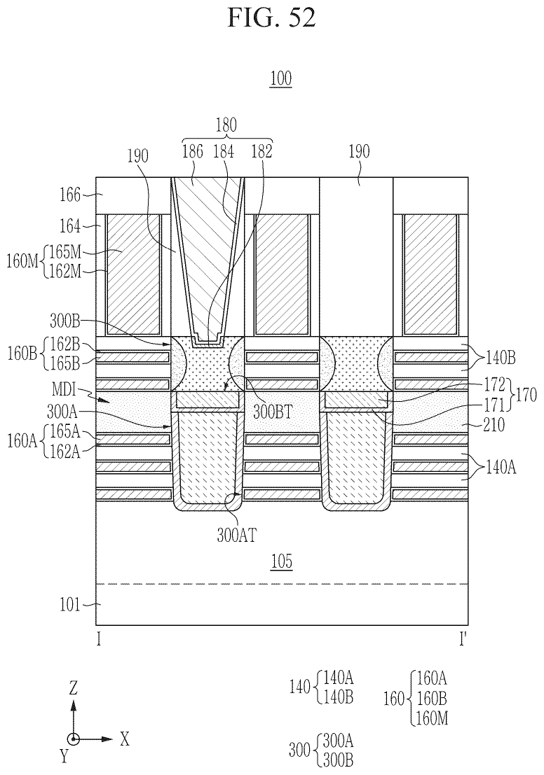

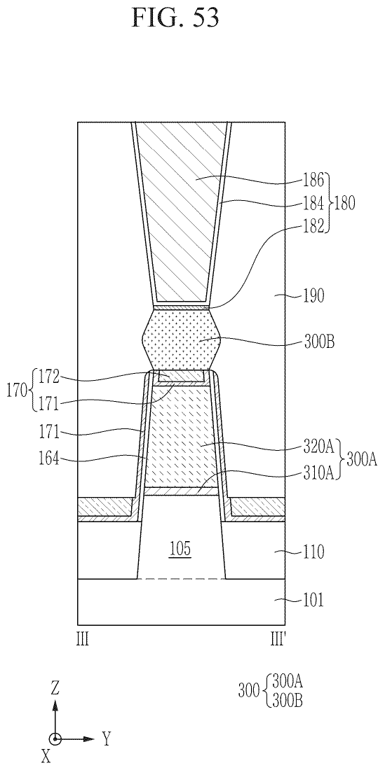

As illustrated in FIGS. 52 and 53, after forming a contact hole that penetrates the interlayer insulation layer 190 to expose the upper source/drain pattern 300B, a contact structure 180 that is electrically connected to the upper source/drain pattern 300B while filling the contact hole may be formed. The contact structure 180 may be electrically connected to the upper source/drain pattern 300B through the interlayer insulation layer 190. The contact structure 180 may include a contact electrode 186, a first barrier layer 184 surrounding the contact electrode 186, and a first silicide film 182 positioned between the first barrier layer 184 and the upper source/drain pattern 300B. Accordingly, the semiconductor device 100 according to the implementation may be manufactured.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

Although an implementation of the present disclosure has been described in detail, the scope of the present disclosure is not limited by the implementation. Various changes and modifications using the basic concept of the present disclosure defined in the accompanying claims by those skilled in the art shall be construed to belong to the scope of the present disclosure.

What is claimed is:

1. A semiconductor device comprising:
a plurality of lower channel patterns spaced apart from each other;
a plurality of upper channel patterns spaced apart from each other on the plurality of lower channel patterns;
a gate structure surrounding the plurality of lower channel patterns and the plurality of upper channel patterns;
a lower source/drain trench positioned at a side of the plurality of lower channel patterns;
an upper source/drain trench positioned at a side of the plurality of upper channel patterns;
a lower source/drain pattern positioned within the lower source/drain trench; and
an upper source/drain pattern including first upper source/drain layers positioned at opposite sidewalls of the upper source/drain trench, and a second upper source/drain layer positioned between the first upper source/drain layers,
wherein the first upper source/drain layers expose at least a portion of the bottom surface of the upper source/drain trench.

2. The semiconductor device of claim 1, wherein:
a top surface of the second upper source/drain layer is flat, and
a side of the first upper source/drain layers includes a curved surface.

3. The semiconductor device of claim 2, wherein:
a maximum width of the first upper source/drain layers is greater than 0 nm and less than 10 nm.

4. The semiconductor device of claim 2, wherein the side of the first upper source/drain layers includes:
a first side extending from a sidewall of the upper source/drain trench and having a rounded shape; and
a second side extending parallel to the sidewall of the upper source/drain trench.

5. The semiconductor device of claim 4, wherein:
an angle formed by the side of the first upper source/drain layers and the sidewall of the upper source/drain trench is between 80 degrees and 90 degrees.

6. The semiconductor device of claim 2, wherein:
the upper source/drain pattern includes silicon germanium, and
a concentration of germanium contained in the second upper source/drain layer is equal to or greater than 60 at % and less than 70 at %.

7. The semiconductor device of claim 1, wherein:
a top surface of the second upper source/drain layer has a convex shape in a direction away from the lower source/drain pattern towards the substrate.

8. The semiconductor device of claim 1, wherein:
the first upper source/drain layers are in contact with the plurality of upper channel patterns, and
the second upper source/drain layer is separate from the plurality of upper channel patterns.

9. The semiconductor device of claim 1, wherein:
a side of the first upper source/drain layers includes a plurality of inclined surfaces having different inclinations.

10. The semiconductor device of claim 1, wherein:
a width of the first upper source/drain layers increases or stays the same as the width moves from a lower portion of the supper source/drain trench forwards a central portion of the upper source/drain trench.

11. The semiconductor device of claim 1, further comprising:
a barrier structure positioned between the lower source/drain pattern and the upper source/drain pattern,
wherein a bottom surface of the second upper source/drain layer is in contact with at least a portion of the barrier structure.

12. The semiconductor device of claim 11, further comprising:
an air gap positioned between the barrier structure and the second upper source/drain layer,
wherein the air gap overlaps the lower source/drain pattern in a perpendicular direction, and
a bottom surface of the second upper source/drain layer has a convex shape toward the lower source/drain pattern.

13. A semiconductor device comprising:
a plurality of upper channel patterns spaced apart from each other;
a gate structure surrounding the plurality of upper channel patterns;
an upper source/drain trench positioned at a side of the plurality of upper channel patterns; and
an upper source/drain pattern including first upper source/drain layers protruding from opposite sidewalls of the upper source/drain trench, and a second upper source/drain layer positioned between the first upper source/drain layers,
wherein a width of the first upper source/drain layers gradually increases from an upper portion and a lower portion of the upper source/drain trench toward a center portion of the upper source/drain trench.

14. The semiconductor device of claim 13, wherein:
a side of the first upper source/drain layers includes a curved surface,
a top surface of the second upper source/drain layer is flat or has a convex shape in a direction from a contact structure towards the substrate.

15. The semiconductor device of claim 14, wherein:
the side of the first upper source/drain layers includes
a first side extending from a sidewall of the upper source/drain trench and having a rounded shape; and
a second side extending in a parallel direction as the sidewall of the upper source/drain trench.

16. A semiconductor device comprising:
a substrate;
an active pattern positioned on the substrate;
a plurality of lower channel patterns spaced apart on the active pattern;
a plurality of upper channel patterns spaced apart on the plurality of lower channel patterns;
a gate structure surrounding the plurality of lower channel patterns and the plurality of upper channel patterns;
a lower source/drain pattern positioned at a side of the plurality of lower channel patterns;
an upper source/drain pattern including first upper source/drain layers and a second upper source/drain layer positioned at a side of the plurality of upper channel patterns; and
a barrier structure positioned between the lower source/drain pattern and the upper source/drain pattern,
wherein the first upper source/drain layers are positioned at opposite sides of the second upper source/drain layer, and
a width of the first upper source/drain layers along one direction gradually increases from an upper portion and a lower portion of an upper source/drain trench toward a center portion of the upper source/drain trench.

17. The semiconductor device of claim 16, wherein:
a side of the first upper source/drain layers includes a rounded shape, and
a top surface of the second upper source/drain layer is flat or has a convex shape in a direction from a contact structure towards the substrate.

18. The semiconductor device of claim 17, wherein:
the upper source/drain pattern includes silicon germanium,
a concentration of germanium contained in the second upper source/drain layer is greater than a concentration of germanium contained in the first upper source/drain layer, and
the concentration of germanium contained in the second upper source/drain layer is equal to or greater than 60 at % and less than 70 at %.

19. The semiconductor device of claim 17, wherein:
a top surface of the second upper source/drain layer is positioned farther from a top surface of the substrate than a top surface of a topmost upper channel pattern among the plurality of upper channel patterns, or is positioned equally spaced to the top surface of the topmost upper channel pattern from a top surface of the substrate.

20. The semiconductor device of claim 16, wherein:
the first upper source/drain layers expose at least a portion of the top surface of the barrier structure.
